(19) United States
(12) Patent Application Publication
(10) Pub. No.: US 2020/0091448 A1
(43) Pub. Date: Mar. 19, 2020

(54) THREE-DIMENSIONAL (3D) CARBON NANOTUBE GATE METAL OXIDE (MOS) FIELD-EFFECT TRANSISTORS (FETs) (MOSFETS), AND RELATED FABRICATION PROCESSES

(71) Applicant: QUALCOMM Incorporated, San Diego, CA (US)

(72) Inventors: Xia Li, San Diego, CA (US); Bin Yang, San Diego, CA (US); Gengming Tao, San Diego, CA (US)

(21) Appl. No.: 16/130,457

(22) Filed: Sep. 13, 2018

(51) Int. Cl. H01L 51/05; H01L 51/00; H01L 27/06

(52) U.S. Cl. CPC H01L 51/0512; H01L 29/7855; H01L 27/0688; H01L 51/0048

(57) ABSTRACT

Three-dimensional (3D) carbon nanotube gate field-effect transistors (FETs), that use carbon nanotubes to form a gate, and related fabrication methods are disclosed. A carbon nanotube gate can provide for greater channel control and enlarge the effective channel width of the 3D FET, thus increasing drive strength. Carbon nanotubes have lower surface scatter and have been found to be diffusive such that resistance dominates carrier transport, thus causing higher carrier mobility. A 3D FET can be provided that includes a gate formed from carbon nanotube(s) disposed adjacent to a semiconductor channel formed from a carbon nanotube(s). A dual-gate FET can be provided employing a carbon nanotube gate(s) comprising a front and back carbon nanotube with a semiconductor channel formed therebetween.

### BACKGROUND

### I. Field of the Disclosure

The technology of the disclosure relates generally to semiconductor devices, and more specifically, to three-dimensional (3D) Field-Effect Transistors (FETs), such as FinFETs and gate-all-around (GAA) FETs.

II. Background

Transistors are essential components in modern electronic devices. Large numbers of transistors are employed in integrated circuits (ICs) in many modem electronic devices. For example, components such as central processing units (CPUs), digital signal processors (DSPs), and memory systems each employ a large quantity of transistors for logic circuits and memory devices.

As electronic devices become more complex in functionality, so does the need to include a greater number of transistors in such devices. But as electronic devices are required to be provided in increasingly smaller packages, such as in mobile devices for example, there is need to provide a greater number of transistors in a smaller IC chip. This increase in the number of transistors is achieved in part through continued efforts to miniaturize transistors in ICs (i.e., placing increasingly more transistors into the same amount of space). In particular, node sizes in ICs are being scaled down by a reduction in minimum gate width in the ICs (e.g., 65 nanometers (nm), 45 nm, 28 nm, 20 nm, etc.). As a result, the gate lengths of planar transistors are also scalably reduced, thereby reducing the channel length of the transistors and interconnects. Reduced channel length in planar transistors has the benefit of increasing drive strength (i.e., increased drain current) with smaller parasitic capacitances resulting in reduced circuit delay. However, as channel length in planar transistors is reduced such that the channel length is of the same order of magnitude as the depletion layer widths, short channel effects (SCEs) can occur that degrade performance. More specifically, SCEs in planar transistors can cause increased current leakage, reduced threshold voltage, and/or threshold voltage roll-off (i.e., reduced threshold voltage at shorter gate lengths).

In this regard, to address the need to scale down channel lengths in transistors while avoiding or mitigating the effect of SCEs, alternative transistor designs to planar transistors have been developed. For example, a Fin field-effect transistor (FET) (FinFET) has been developed that provides a conducting channel wrapped by a thin silicon “fin,” which forms the gate of the device. In this regard, FIG. 1A illustrates an exemplary FinFET 100. The FinFET 100 includes a body 102 (e.g., an oxide layer). The FinFET 100 includes a source 104 and a drain 106 interconnected by a Fin 108 that includes a conduction channel 110 (“channel 110”), as shown in FIG. 1B. The Fin 108 is surrounded by a “wrap-around” metal gate 112 (“gate 112”). FIG. 1B illustrates a close-up cross-sectional side view of the FinFET 100 in FIG. 1A along an A-A line. As shown in FIG. 1B, an interfacial layer 114 and a dielectric material layer 116 are disposed around the channel 110 to insulate the gate 112 from the channel 110. The wrap-around structure of the gate 112 around the channel 110 provides better electrical control over the channel 110, and thus assists in reducing the leakage current and overcoming other SCEs. The thickness DFin of the Fin 108 (measured in the direction from the source 104 to the drain 106) determines the effective channel length of the FinFET 100.

FIGS. 2A and 2B illustrate perspective and side views, respectively, of an exemplary nanoslab FET 200 that is a gate-all-around (GAA) device. As shown in FIG. 2A, the nanoslab FET 200 includes a channel body 202 that includes a nanoslab channel structure 204 that includes a plurality of nanoslab structures 206(1)-206(3) that form a channel. In this example, the nanoslab structures 206(1)-206(3) are in the form of nanoslabs 208(1)-208(3). FIG. 2B illustrates a side view of the channel body 202 in the nanoslab FET 200 in FIG. 2A. As shown in FIGS. 2A and 2B, a gate material 210 in the form of a metal material completely surrounds the nanoslab structures 206(1)-206(3). Before the gate material 210 is disposed, an interfacial layer 212(1)-212(3) is disposed around the respective nanoslab structures 206(1)-206(3) followed by a high-K dielectric material layer 214(1)-214(3) to insulate the gate material 210 from the nanoslab structures 206(1)-206(3). In this manner, applying a voltage to the gate material 210 controls an electric field in the nanoslab structures 206(1)-206(3) to cause current to flow through the nanoslab structures 206(1)-206(3) during an active mode. The length of the nanoslab structures 206(1)-206(3) is each of a height of Twire. The overall length and perimeter, respectively, of the nanoslab structures 206(1)-206(3) determine the effective nanoslab length in the channel body 202, and the drive strength of the nanoslab FET 200. Drive strength of nanoslab FETs is also determined the number of vertically stacked nanoslab. Adjacent nanoslab structures 206(1)-206(3) are separated a distance from each other (labeled ‘Tsus’) in FIG. 2A. This distance Tsus is provided of a distance based on fabrication limitations to allow the gate material 210 to be disposed completely around and between the adjacent nanoslab structures 206(1)-206(3) so that the gate material 210 can provide gate control of the channels formed by the nanoslab structures 206(1)-206(3) to control the channel of the nanoslab FET 200.

There is continued pressure to improve the processing capabilities of ICs, which results in pressure to increase a number of transistors present on a given IC. This pressure, coupled with pressure from mobile device users, has resulted in reductions in the size of the transistors. For example, the node size for GAA FETs (i.e., the spacing between elements in the IC) has reached 10 nm, and in some cases 7 nm. GAA FETs can be designed to have a lower threshold voltage than similar FinFET devices, because GAA. FETs have better short channel control. This allows a reduction in supply voltage, which results in a quadratic reduction in power consumption because of voltage scaling. However, disadvantages of GAA FETs are increased resistance resulting in increased current-resistance (IR) drop and increased capacitance due to coupling between source/drain and gate. GAA FETs also suffer from an area penalty over FinFETs when more than one active semiconductor fin is employed for drive strength requirements. It is desired for the node size of GAA FETs to be further reduced to mitigate or offset area penalty, but the quantum limitations of GAA FETs may be reached at a node size of approximately 5 nm. GAA fin patterning may also be challenging for a 5 nm node size and beyond to 2-3 nm technology. Semiconductor photolithography resolution limits available for extreme ultraviolet (EUV) lithography and etching equipment to fabricate GAA FETs may also be reached as node size is reduced. Even with EUV lithography, the size of the nodes may be smaller than the wavelength of the lithographic technique. For example, a common EUV wavelength is around 13.5 nm. Semiconductor material, such as Silicon (Si), Silicon Germanium (SiGe), Gallium Arsenide (GaAs), etc., also has limited mobility defined by line edge roughness and the surface phonon scatter effect.

### SUMMARY OF THE DISCLOSURE

Aspects disclosed herein include three-dimensional (3D) carbon nanotube gate field-effect transistors (FETs), and related fabrication methods. Use of carbon nanotubes to form gates in a 3D FET can provide for greater channel control and enlarge the effective channel width of the 3D FET thus increasing drive strength. Carbon nanotubes have lower surface scatter and have been found to be diffusive such that resistance dominates carrier transport, thus causing carrier mobility to exceed the carrier mobility of other semiconductor structures. N-type metal oxide semiconductor (NMOS) and P-type MOS (PMOS) FETs can be fabricated with gates formed from carbon nanotubes. Carbon nanotubes can also be used to form semiconductor channels in a 3D FET for increased channel mobility to further enlarge the effective channel width of the 3D FET and increase drive strength. The carbon nanotubes can be pre-fabricated and then transferred to a substrate to form a carbon nanotube gate. Transferring the carbon nanotubes can avoid more complex and expensive fin patterning processes which may be limited to extreme ultraviolet (EUV) lithography and etching processes for example. The 3D multiple-layer, carbon nanotube FET can be fabricated as part of a complementary MOS (CMOS) fabrication process.

In this regard, in one exemplary aspect, a 3D FET can be provided that employs that includes a gate formed from carbon nanotube(s) disposed adjacent to a semiconductor channel formed from a carbon nanotube(s). In another exemplary aspect, a 3D dual-gate FET can be provided that employs a carbon nanotube gates) of a front and back carbon nanotube and a semiconductor channel of a carbon nanotube(s) disposed therebetween. In another exemplary aspect, multiple carbon nanotubes can be transferred below and above an interleaving semiconductor channel structure to form a 3D dual-gate carbon nanotube FET for enhanced channel control and carrier mobility.

In this regard, in one exemplary aspect, a 3D FET is provided. The 3D FET comprises a substrate comprising a top surface. The 3D FET also comprises a dielectric layer disposed on the top surface of the substrate. The 3D FET also comprises a carbon nanotube channel disposed above the dielectric layer, the carbon nanotube channel comprising at least one carbon nanotube channel structure. Each of the at least one carbon nanotube channel structure comprises a carbon nanotube having a first length and having a first longitudinal axis, and a channel dielectric material surrounding at least a portion of the carbon nanotube. The 3D FET also comprises a carbon nanotube gate disposed above a portion of the carbon nanotube channel, the carbon nanotube gate comprising a carbon nanotube having a second longitudinal axis substantially orthogonal to the first longitudinal axis.

In another exemplary aspect, a method of fabricating a 3D FET is provided. The method comprises disposing a dielectric layer disposed on a top surface of a substrate. The method also comprises transferring at least one carbon nanotube to a top surface of the dielectric layer to form a carbon nanotube channel structure, wherein the at least one carbon nanotube has a first length and has a first longitudinal axis. The method also comprises disposing a channel dielectric layer over the at least one carbon nanotube. The method also comprises transferring a second carbon nanotube above the channel dielectric layer and above a portion of the carbon nanotube channel structure to form a carbon nanotube gate having a second longitudinal axis substantially orthogonal to the first longitudinal axis and comprising a first gate side extending in the direction of the second longitudinal axis and a second gate side opposite the first gate side extending in the direction of the second longitudinal axis. The method also comprises forming a second dielectric layer above the carbon nanotube gate.

In another exemplary aspect, a 3D FET is provided. The 3D FET comprises a substrate comprising a top surface. The 3D FET also comprises a dielectric layer disposed on the top surface of the substrate. The 3D FET also comprises a back carbon nanotube gate disposed above the dielectric layer, the back carbon nanotube gate having a first longitudinal axis. The 3D FET also comprises a semiconductor channel comprising a semiconductor channel structure disposed above the back carbon nanotube gate, the semiconductor channel having a second length and having a second longitudinal axis substantially orthogonal to the first longitudinal axis. The 3D FET also comprises a first channel dielectric layer disposed between the back carbon nanotube gate and the semiconductor channel. The 3D FET also comprises a second channel dielectric layer disposed on a top surface of the semiconductor channel. The 3D FET also comprises a front carbon nanotube gate disposed on a top surface of the second channel dielectric layer, the front carbon nanotube gate having a third longitudinal axis substantially parallel to the first longitudinal axis.

In another exemplary aspect, a method of fabricating a 3D FET is provided. The method comprises disposing a dielectric layer disposed on a top surface of a substrate. The method also comprises transferring a back carbon nanotube gate to a top surface of the dielectric layer, the back carbon nanotube gate having a first longitudinal axis. The method also comprises disposing a first channel dielectric layer on the back carbon nanotube gate. The method also comprises disposing a semiconductor channel structure to a top surface of the first channel dielectric layer to form a semiconductor channel, the semiconductor channel structure having a second longitudinal axis substantially orthogonal to the first longitudinal axis. The method also comprises disposing a second channel dielectric layer on a top surface of the semiconductor channel structure. The method also comprises transferring a front carbon nanotube gate on a top surface of the second channel dielectric layer, the front carbon nanotube gate having a third longitudinal axis substantially parallel to the first longitudinal axis.

### BRIEF DESCRIPTION OF THE FIGURES

FIG. 1A illustrates an exemplary fin Field-Effect Transistor (FET) (FinFET);

FIG. 1B is a close-up cross-sectional side view of the fin in the fin field-effect transistor (FET) (FinFET) in FIG. 1A along the A-A line;

FIGS. 2A and 2B are front perspective and front views of an exemplary nanoslab FET;

FIGS. 3A and 3B are front perspective and side views, respective of an exemplary 3D carbon nanotube FET in the form of a 3D carbon nanotube gate FET that employs a carbon nanotube gate(s) disposed adjacent to a semiconductor channel formed by one or more carbon nanotubes;

FIG. 4 is a flowchart illustrating an exemplary process of fabricating the 3D carbon nanotube gate FET in FIGS. 3A and 3B;

FIG. 5A is a front perspective view of an exemplary fabrication stage of forming a substrate and a dielectric layer on the substrate, for fabricating the 3D carbon nanotube gate FET in FIGS. 3A and 3B;

FIG. 5B is a front perspective view of an exemplary fabrication stage of transferring carbon nanotubes to the dielectric layer in the fabrication stage in FIG. 5A to form a semiconductor channel, for fabricating the 3D carbon nanotube gate FET in FIGS. 3A and 3B;

FIG. 5C is a front perspective view of an exemplary fabrication stage of forming a high-k dielectric material layer (e.g., an oxide) on the carbon nanotubes in the fabrication stage in FIG. 5B forming the semiconductor channel, and transferring a carbon nanotube on the high-k dielectric material layer to form a carbon nanotube gate, for fabricating the 3D carbon nanotube gate FET in FIGS. 3A and 3B;

FIG. 5D is a front perspective view of an exemplary fabrication stage of forming an oxide and film layer on the carbon nanotube gate and etching the film layer to form spacers around the carbon nanotube gate, for fabricating the 3D carbon nanotube gate FET in FIGS. 3A and 3B;

FIG. 5E is a front perspective view of an exemplary fabrication stage of forming a first interlayer dielectric material (ILD) above the carbon nanotube gate after the fabrication stage in FIG. 5D and transferring carbon nanotubes to a second dielectric layer to form a second semiconductor channel, for fabricating the 3D carbon nanotube gate FET in FIGS. 3A and 3B;

FIG. 5F is a front perspective view of an exemplary fabrication stage of forming a second high-k dielectric material layer (e.g., an oxide) on the carbon nanotubes in the fabrication stage in FIG. 5E forming the second semiconductor channel, and transferring a second carbon nanotube on the second high-k dielectric material layer to form a second carbon nanotube gate, for fabricating the 3D carbon nanotube gate FET in FIGS. 3A and 3B;

FIG. 5G is a front perspective view of an exemplary fabrication stage of forming a second oxide and second film layer on the second carbon nanotube gate and etching the second film layer to form spacers around the second carbon nanotube gate, for fabricating the carbon nanotube gate 3D FET in FIGS. 3A and 3B;

FIG. 5H is a front perspective view of an exemplary fabrication stage of forming a second ILD on the second carbon nanotube gate and performing a planarization process, for fabricating the 3D carbon nanotube gate FET in FIGS. 3A and 3B;

FIG. 5I is a front perspective view of an exemplary fabrication stage of performing a lithography printing and a pattered etch to remove a portion of the second dielectric layer on opposing sides of the carbon nanotube gates in a source and drain region of the fabrication stage in FIG. 5H for forming a respective source and drain, for fabricating the 3D carbon nanotube gate FET in FIGS. 3A and 3B;

FIG. 5J is a front perspective view of an exemplary fabrication stage the 3D carbon nanotube gate FET in FIGS. 3A and 3B after the fabrication steps in FIGS. 5A-5I;

FIGS. 6A and 6B are front perspective and side views, respective of an exemplary 3D carbon nanotube FET in the form of a 3D carbon nanotube dual-gate FET that employs a dual-gate disposed on adjacent sides of a carbon nanotube channel structure;

FIG. 7 is a flowchart illustrating an exemplary process of fabricating the 3D carbon nanotube dual-gate FET in FIGS. 6A and 6B;

FIG. 8A is a front perspective view of an exemplary fabrication stage of transferring a carbon nanotube to a dielectric layer formed on a substrate to form a back carbon nanotube gate as part of a dual carbon nanotube gate to be formed, for fabricating the 3D carbon nanotube dual-gate FET in FIGS. 6A and 6B;

FIG. 8B is a front perspective view of an exemplary fabrication stage of forming a high-k dielectric material layer (e.g., an oxide) on the back carbon nanotube gate in the fabrication stage in FIG. 8A, for fabricating the 3D carbon nanotube dual-gate FET in FIGS. 6A and 6B;

FIG. 8C is a front perspective view of an exemplary fabrication stage of forming a semiconductor channel on the high-k dielectric material layer in the fabrication stage in FIG. 8B and forming a second high-k dielectric material layer (e.g., an oxide) on the semiconductor channel, and performing a lithography printing and a pattered etch to remove a portion of the second high-k dielectric layer and transition metal layer, for fabricating the 3D carbon nanotube dual-gate FET in FIGS. 6A and 6B;

FIG. 8D is a front perspective view of an exemplary fabrication stage of transferring a second carbon nanotube to the second high-k dielectric material layer formed in the fabrication stage of FIG. 8C to provide a front carbon nanotube gate as part of a dual carbon nanotube gate, for fabricating the 3D carbon nanotube dual-gate FET in FIGS. 6A and 6B;

FIG. 8E is a front perspective view of an exemplary fabrication stage of forming a second transition metal layer on a third high-k dielectric material layer formed above the front carbon nanotube gate in the fabrication stage in FIG. 8D and forming the second high-k dielectric material layer (e.g., an oxide) on the second transition metal layer, and performing a lithography printing and a pattered etch to remove a portion of the third high-k dielectric layer and second transition metal layer, for fabricating the 3D carbon nanotube dual-gate FET in FIGS. 6A and 6B;

FIG. 8F is a front perspective view of an exemplary fabrication stage of transferring a third carbon nanotube to the third high-k dielectric material layer formed in the fabrication stage of FIG. 8E to provide a second front carbon nanotube gate as part of a second dual carbon nanotube gate wherein the front carbon nanotube gate of the first dual carbon nanotube gate forms the back carbon nanotube gate of the second dual carbon nanotube gate, for fabricating the 3D carbon nanotube dual-gate FET in FIGS. 6A and 6B;

FIG. 8G is a front perspective view of an exemplary fabrication stage of forming an oxide and film layer on and around first and second dual carbon nanotube gates formed in the fabrication stage in FIGS. 8A-8F and etching the film layer to form spacers around first and second dual carbon nanotube gates, for fabricating the 3D carbon nanotube dual-gate FET in FIGS. 6A and 6B;

FIG. 8H is a front perspective view of an exemplary fabrication stage of forming an ILD on the spacer in the fabrication stage in FIG. 8G and performing a planarization process, for fabricating the 3D carbon nanotube dual-gate FET in FIGS. 6A and 6B;

FIG. 8I is a front perspective view of an exemplary fabrication stage of performing a lithography printing and a pattered etch to remove a portion of the ILD on opposing sides of the first and second carbon nanotube gates in a source and drain region of the fabrication stage in FIG. 8H for forming a respective source and drain, for fabricating the 3D carbon nanotube dual-gate FET in FIGS. 6A and 6B;

FIG. 8J is a front perspective view of an exemplary fabrication stage of the 3D carbon nanotube dual-gate FET in FIGS. 6A and 6B after the fabrication steps in FIGS. 8A-8I;

FIG. 9 is a block diagram of an exemplary processor-based system that can include a carbon nanotube gate FET including but not limited to the 3D carbon nanotube gate FET in FIGS. 3A and 3B, and the 3D carbon nanotube dual-gate FET in FIGS. 6A and 6B; and

FIG. 10 is a block diagram of an exemplary wireless communications device that includes radio frequency (RF) components formed from an integrated circuit (IC), wherein any of the components therein can include a carbon nanotube gate FET including but not limited to the 3D carbon nanotube gate FET in FIGS. 3A and 3B, and the 3D carbon nanotube dual-gate FET in FIGS. 6A and 6B.

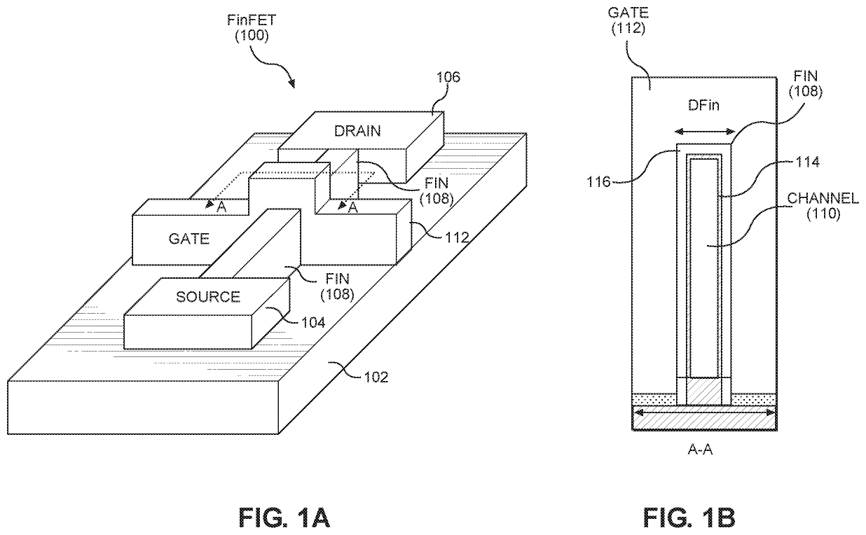

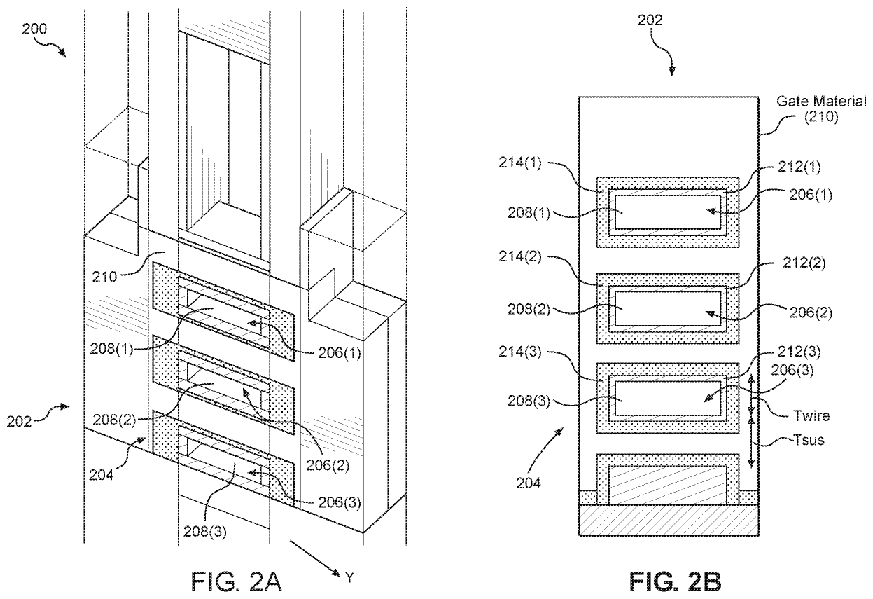

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include three-dimensional (3D) carbon nanotube gate field-effect transistors (FETs), and related fabrication methods. Use of carbon nanotubes to form gates in a 3D FET can provide for greater channel control and enlarge the effective channel width of the 3D FET thus increasing drive strength. Carbon nanotubes have lower surface scatter and have been found to be diffusive such that resistance dominates carrier transport, thus causing carrier mobility to exceed the carrier mobility of other semiconductor structures. N-type metal oxide semiconductor (NMOS) and P-type MOS (PMOS) FETs can be fabricated with gates formed from carbon nanotubes. Carbon nanotubes can also be used to form semiconductor channels in a 3D FET for increased channel mobility to further enlarge the effective channel width of the 3D FET and increase drive strength. The carbon nanotubes can be pre-fabricated and then transferred to a substrate to form a carbon nanotube gate. Transferring the carbon nanotubes can avoid more complex and expensive fin patterning processes which may be limited to extreme ultraviolet (EUV) lithography and etching processes for example. The 3D multiple-layer, carbon nanotube FET can be fabricated as part of a complementary MOS (CMOS) fabrication process.

In this regard, in one exemplary aspect, a 3D FET can be provided that employs that includes a gate formed from carbon nanotube(s) disposed adjacent to a semiconductor channel formed from a carbon nanotube(s). In another exemplary aspect, a 3D dual-gate FET can be provided that employs a carbon nanotube gate(s) of a front and back carbon nanotube and a semiconductor channel of a carbon nanotube(s) disposed therebetween. In another exemplary aspect, multiple carbon nanotubes can be transferred below and above an interleaving semiconductor channel structure to form a 3D dual-gate carbon nanotube FET for enhanced channel control and carrier mobility.

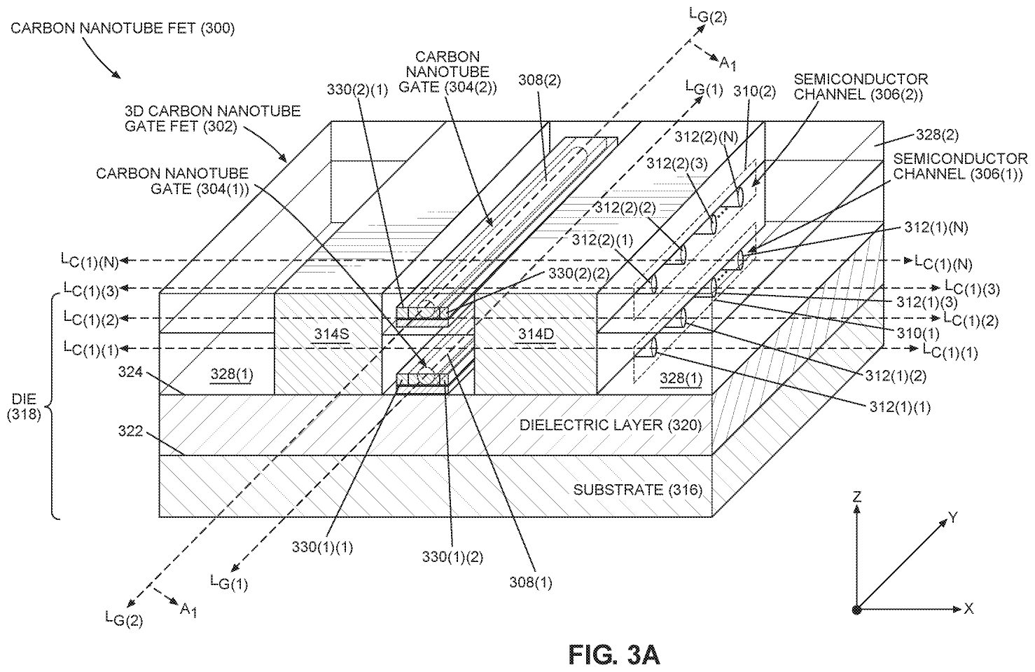

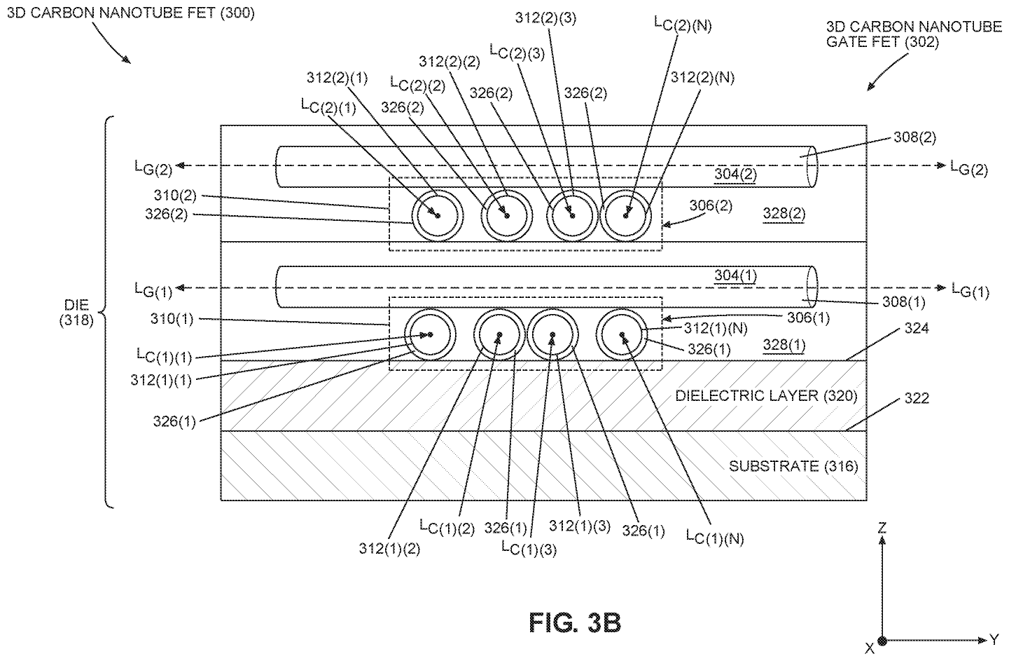

In this regard, FIGS. 3A and 3B are front perspective and side views, respective of an exemplary 3D carbon nanotube FET 300 in the form of a 3D carbon nanotube gate FET 302. FIG. 3B is shown along the cross-sectional line A₁-A₁ in FIG. 3A. The 3D carbon nanotube gate FET 302 in this example includes a plurality of carbon nanotube gates 304(1), 304(2) disposed adjacent to respective carbon nanotube channels 306(1), 306(2), which are semiconductor channels formed from one or more carbon nanotubes. In this example, the carbon nanotube gates 304(1), 304(2) each include a carbon nanotube 308(1), 308(2) that are each disposed around at least a portion of the respective raised carbon nanotube channels 306(1), 306(2) to form a 3D FET structure. As will be discussed below, in this example, each carbon nanotube channel 306(1), 306(2) is a carbon nanotube channel structure 310(1), 310(2) that each include plurality of carbon nanotubes 312(1)(1)-312(1)N, 312(2)(1)-312(2)(N). The number of carbon nanotubes ‘N’ included in each carbon nanotube channel structure 310(1), 310(2) can any positive whole number desired. The carbon nanotube gate 304(1) controls or permits electrons to flow through or blocks their passage between a source 314S and a drain 314D by creating or eliminating a channel through the carbon nanotubes 312(1)(1)-312(1)(N) of the carbon nanotube channel structure 310(1) based on a voltage applied to the carbon nanotube gate 304(1). Similarly, the carbon nanotube gate 304(2) controls or permits electrons to flow through or blocks their passage between the source 314S and the drain 314D by creating or eliminating a channel through the carbon nanotubes 312(2)M-312(2)(N) of the carbon nanotube channel structure 310(2) based on a voltage applied to the carbon nanotube gate 304(2). In this example, including the multiple carbon nanotube gates 304(1), 304(2) and carbon nanotube channel structures 310(1), 310(2) can increase the drive strength of the 3D carbon nanotube gate FET 302 as opposed to use of a single carbon nanotube controlling a single carbon nanotube channel structure, but including multiple carbon nanotube gates 304(1), 304(2) and corresponding carbon nanotube channel structures 310(1), 310(2) is not required.

Use of carbon nanotubes to form gates, such as the carbon nanotube gates 304(1), 304(2) in the 3D carbon nanotube gate FET 302, can provide for greater channel control and enlarge the effective channel width of a 3D FET, thus increasing drive strength. Carbon nanotubes have lower surface scatter and have been found to be diffusive such that resistance dominates carrier transport, thus causing carrier mobility to exceed the carrier mobility of other semiconductor structures. Use of carbon nanotubes to form semiconductor channels, such as the carbon nanotube channels 306(1), 306(2) in the 3D carbon nanotube gate FET 302, can also increase channel mobility to further enlarge the effective channel width of a 3D FET and increase drive strength. As will be discussed in more detail below, the carbon nanotubes 308(1), 308(2) to form the carbon nanotube gates 304(1), 304(2) and the carbon nanotubes 312(1)(1)-312(1)(N), 312(2)(1)-312(2)(N) to form the carbon nanotube channels 306(1), 306(2) can be pre-fabricated and then transferred a substrate or other material layer surface to fabricate the 3D carbon nanotube gate FET 302. N-type metal oxide semiconductor (NMOS) and P-type MOS (PMOS) FETs can be fabricated with gates formed from carbon nanotubes. Transferring the carbon nanotubes can avoid more complex and expensive fin patterning processes which may be limited to extreme ultraviolet (EUV) lithography and etching processes for example. The 3D multiple-layer, carbon nanotube FET can be fabricated as part of a complementary MOS (CMOS) fabrication process.

With continuing reference to FIGS. 3A and 3B, in this example, the 3D carbon nanotube gate FET 302 includes a substrate 316, which may be a Silicon (Si) material layer for example. The substrate 316 is part of a semiconductor die 318 (shown as “die 318” in FIGS. 3A and 3B). A dielectric layer 320 of a dielectric material is disposed on a top surface 322 of the substrate 316 to insulate the source 314S, the drain 314D, the carbon nanotube channel 306(1) and the carbon nanotube gate 304(1) from adjacent devices formed on the substrate 316 in another area of the semiconductor die 318. The carbon nanotube channel 306(1) that includes the carbon nanotube channel structure 310(1) of the carbon nanotubes 312(1)(1)-312(1)(N) is disposed above the dielectric layer 320, and on a top surface 324 of the dielectric layer 320 in this example. As shown in FIG. 3A, each carbon nanotube 312(1)(1)-312(1)(N) is disposed along a longitudinal axis L_{C(1)(1)}-L_{C(1)(N)} disposed in a first direction (X-axis direction in FIG. 3A) that are substantially parallel to each other. The carbon nanotubes 312(1)(1)-312(1)(N) are a sheet of carbon atoms, such as a graphene sheet, formed in a cylindrical shape thereby forming an internal hollow structure. The thickness of the outer walls of the carbon nanotubes 312(1)(1)-312(1)(N) may be 5 nanometers (nm) or less as an example. The carbon nanotubes 312(1)(1)-312(1)(N) are spaced apart, but such placement is not limited to a fabrication limitation such that the carbon nanotubes 312(1)(1)-312(1)(N) can be pre-fabricated and transferred to the semiconductor die 318 instead of being fabricated in the semiconductor die 318. This allows more carbon nanotubes 312(1)(1)-312(1)(N) to be included in the carbon nanotube channel structure 310(1) to increase drive strength.

As shown in FIG. 3B, a first channel dielectric layer 326(1) comprised of a dielectric material, such as a high-K dielectric material, surrounds the carbon nanotubes 312(1)(1)-312(1)(N) (or surrounds a portion of the carbon nanotubes 312(1)(1)-312(1)(N)) to insulate the carbon nanotube 312(1)(1)-312(1)(N) from the carbon nanotube gate 304(1). In this example, each carbon nanotube 312(1)(1)-312(1)(N) has its own surrounding first channel dielectric layer 326(1) for better gate control. The thickness of the first channel dielectric layer 326(1) surrounding the carbon nanotubes 312(1)(1)-312(1)(N) may be half or less of the thickness of the outer walls of the carbon nanotubes 312(1)(1)-312(1)(N) as an example. Examples of materials of the first channel dielectric layer 326(1) include Hafnium Oxide (HfOx), Hafnium Silicon Oxide (HfSiOx), and Hafnium Silicon Oxygen Nitride (HfON). The carbon nanotube gate 304(1) is disposed above a portion of the carbon nanotube channel 306(1). The carbon nanotube 308(1) that forms the carbon nanotube gate 304(1) that has a longitudinal axis L_{G(1)} extending in a second direction (Y-axis direction in FIGS. 3A and 3B) substantially orthogonal to the longitudinal axes L_{C(1)(1)}-L_{C(1)(N)} of the carbon nanotubes 312(1)(1)-312(1)(N)). Spacers 330(1)(1), 330(1)(2) are formed on opposite sides of the carbon nanotube gate 304(1) for insulation of the carbon nanotube gate 304(1). Also, as will be shown in figures of exemplary fabrication stages of the 3D carbon nanotube gate FET 302 described below, the carbon nanotubes 312(1)(1)-312(1)(N) of the carbon nanotube channel structure 310(1) extend beyond the sides of the carbon nanotube gate 304(1) along the longitudinal axis L_{G(1)} wherein the source 314S and drain 314D are formed outside of the carbon nanotube gate 304(1) in contact with the extended carbon nanotubes 312(1)(1)-312(1)(N).

With continuing references to FIGS. 3A and 3B, in this example, because a second carbon nanotube gate 304(2) and carbon nanotube channel 306(2) are in the 3D carbon nanotube gate FET 302, an interlayer dielectric material (ILD) 328(1) is formed over the first carbon nanotube gate 304(1) and carbon nanotube channel 306(1) to provide isolation. The carbon nanotubes 312(2)(1)-312(2)(N) are a sheet of carbon atoms, such as a graphene sheet, formed in a cylindrical shape thereby forming an internal hollow structure. The thickness of the outer walls of the carbon nanotubes 312(2)(1)-312(2)(N) may be 5 nanometers (nm) or less as an example. The carbon nanotubes 312(2)(1)-312(2)(N) are spaced apart, but such placement is not limited to a fabrication limitation such that the carbon nanotubes 312(2)(1)-312(2)(N) can be pre-fabricated and transferred to the semiconductor die 318 instead of being fabricated in the semiconductor die 318. This allows more carbon nanotubes 312(2)(1)-312(2)(N) to be included in the carbon nanotube channel structure 310(2) to increase drive strength.

As shown in FIG. 3B, like the first channel dielectric layer 326(1), a second channel dielectric layer 326(2) comprised of a dielectric material, such as a high-K dielectric material is disposed above the ILD material 328(1) surrounds the carbon nanotubes 312(2)(2)-312(2)(N) (or surrounds a portion of the carbon nanotubes 312(2)(1)-312(2)(N)) to insulate the carbon nanotubes 312(2)(l)-312(2)(N) from the second carbon nanotube gate 304(2). In this example, each carbon nanotube 312(2)(1)-312(2)(N) has its own surrounding channel dielectric layer 326(2) for better gate control. The thickness of the channel dielectric layer 326(2) surrounding the carbon nanotubes 312(2)(1)-312(2)(N) may be half or less of the thickness of the outer walls of the carbon nanotubes 312(2)(1)-312(2)(N) as an example. Examples of materials of the second channel dielectric layer 326(2) include Hafnium Oxide (HfOx), Hafnium Silicon Oxide (HfSiOx), and Hafnium Silicon Oxygen Nitride (HfON). The second carbon nanotube gate 304(2) is disposed above a portion of the carbon nanotube channel 306(2). The carbon nanotube 308(2) that forms the carbon nanotube gate 304(2) has a longitudinal axis L_{G(2)} extending in a second direction (Y-axis direction in FIGS. 3A and 3B) substantially orthogonal to the longitudinal axes L_{C(2)(1)}-L_{C(2)(N)} of the carbon nanotubes 312(2)(1)-312(2)(N) as shown in FIG. 3B. Spacers 330(2)(1), 330(2)(2) are formed on opposite sides of the carbon nanotube gate 304(2) for insulation of the carbon nanotube gate 304(2) as shown in FIG. 3A. Also, as will be shown in figures of exemplary fabrication stages of the 3D carbon nanotube gate FET 302 described below, the carbon nanotubes 312(2)(1)-312(2)(N) of the carbon nanotube channel structure 310(2) extend beyond the sides of the carbon nanotube gate 304(2) along the longitudinal axis L_{G(2)} wherein the source 314S and drain 314D are formed outside of the carbon nanotube gate 304(2) in contact with the extended the carbon nanotubes 312(2)(1)-312(2)(N). A second ILD 328(2) is formed over the second carbon nanotube gate 304(2) and carbon nanotube channel 306(2) to provide isolation.

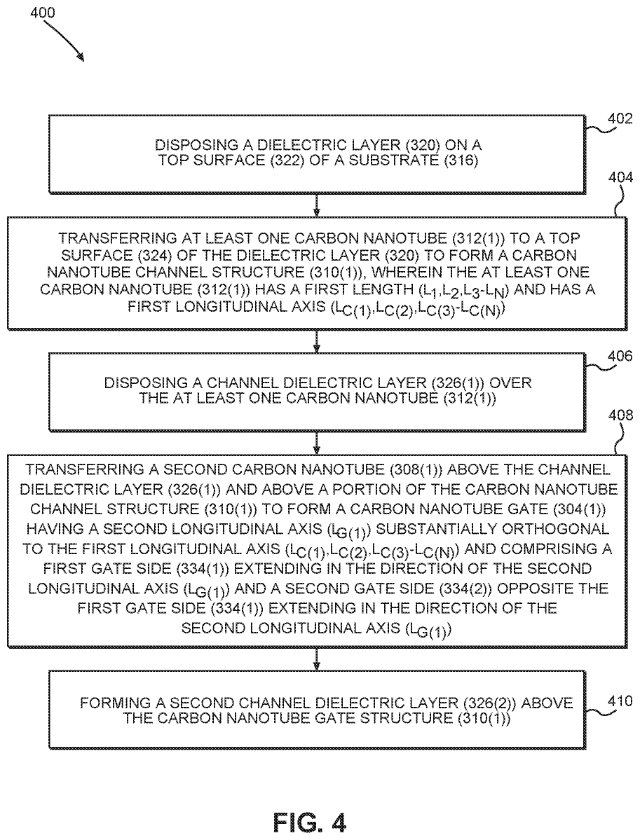

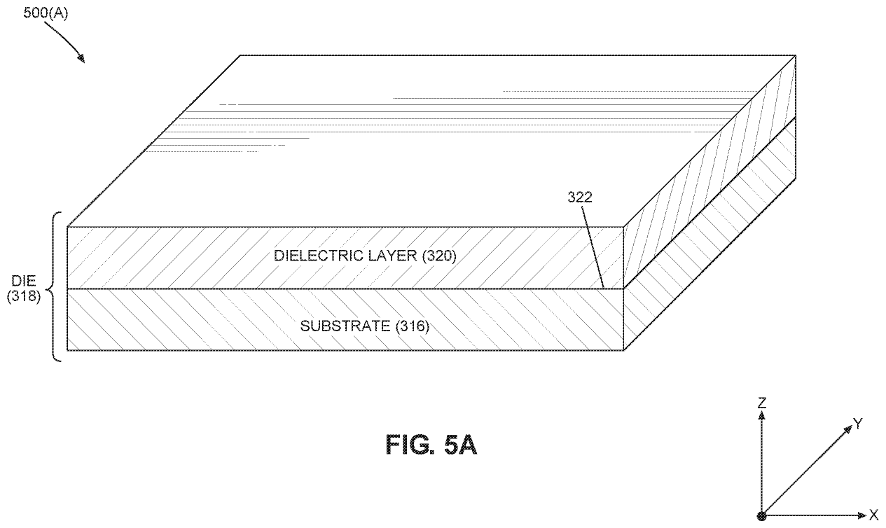

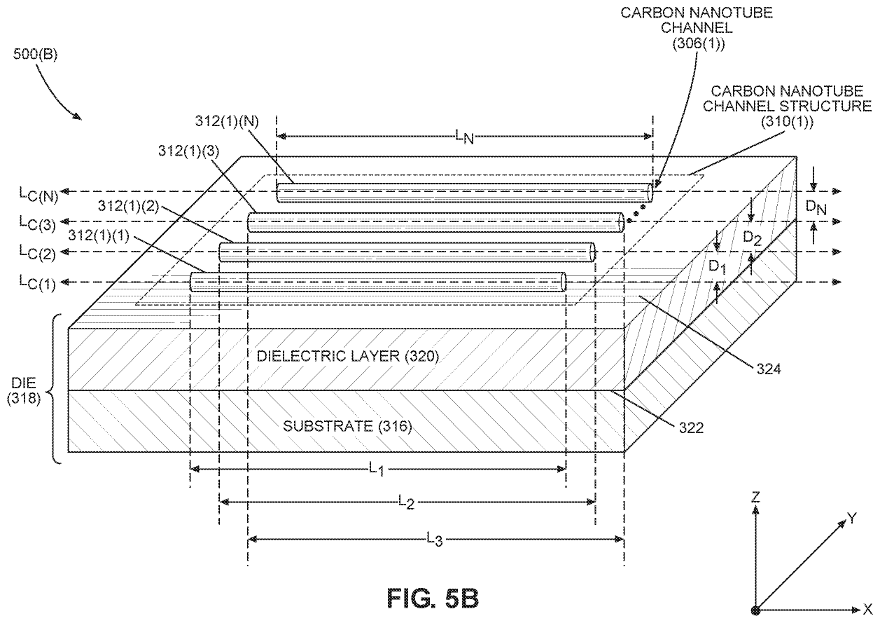

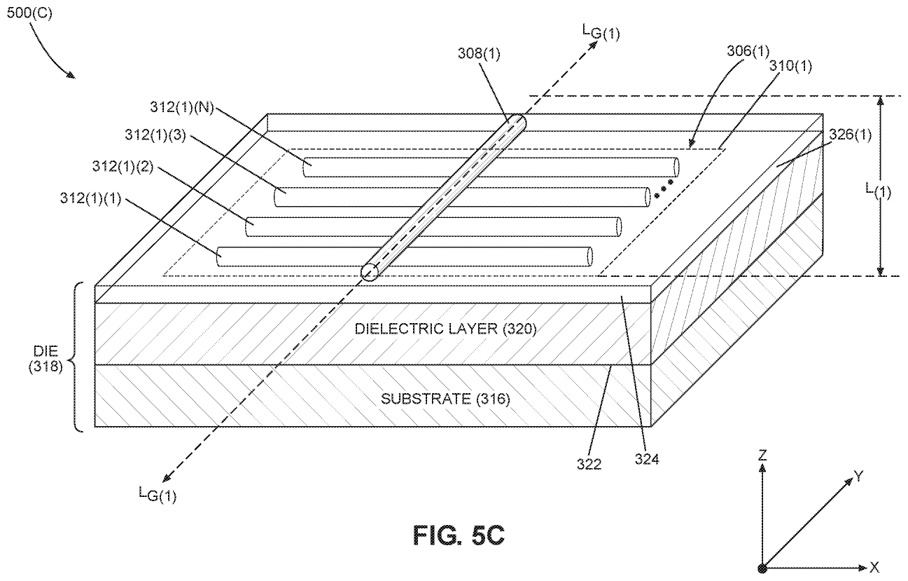

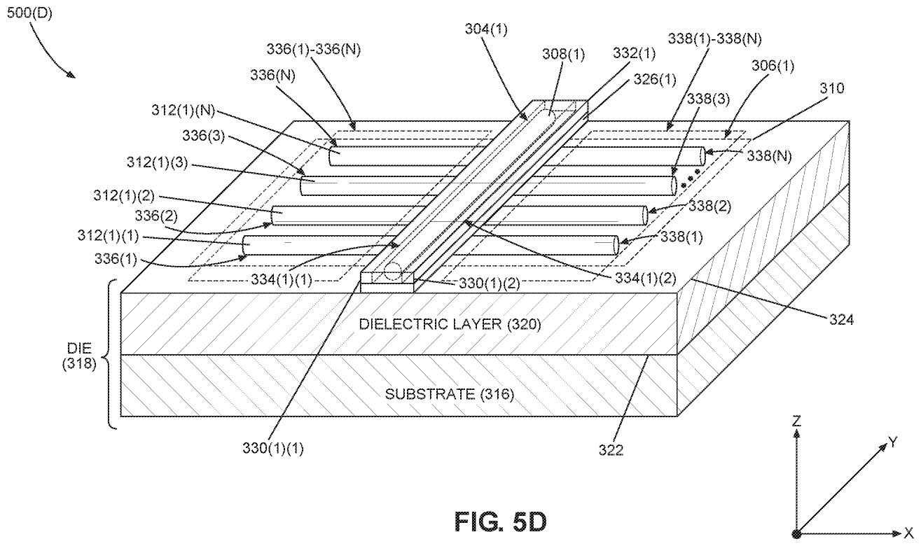

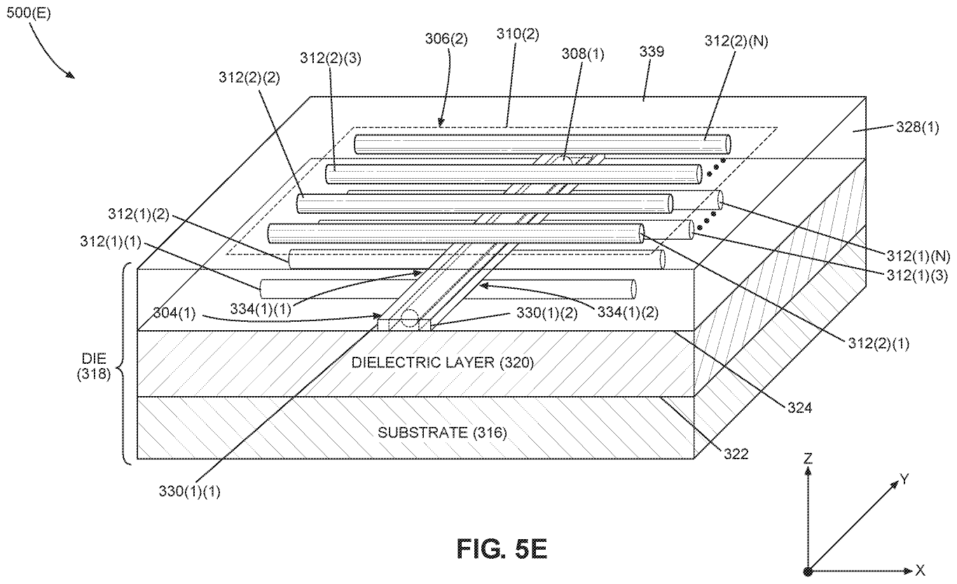

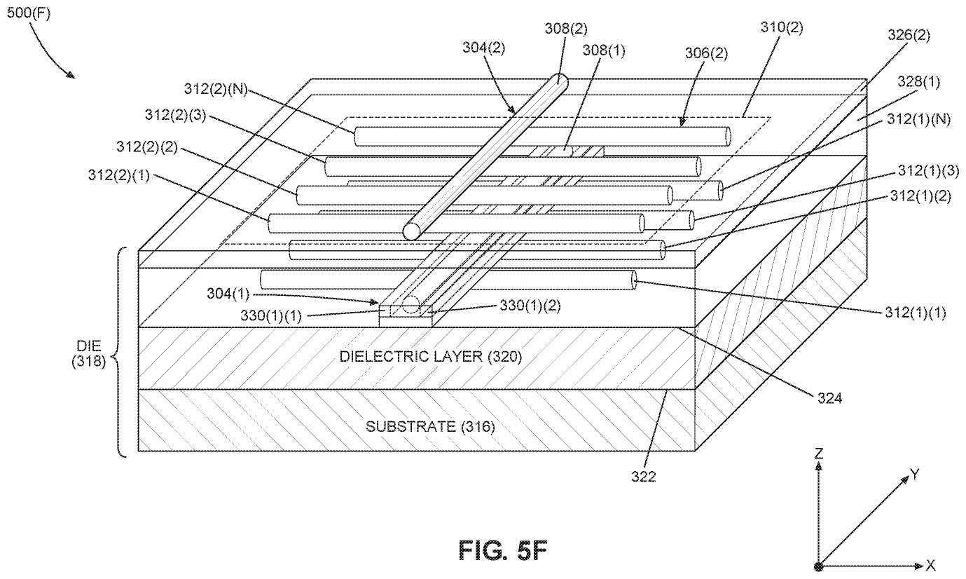

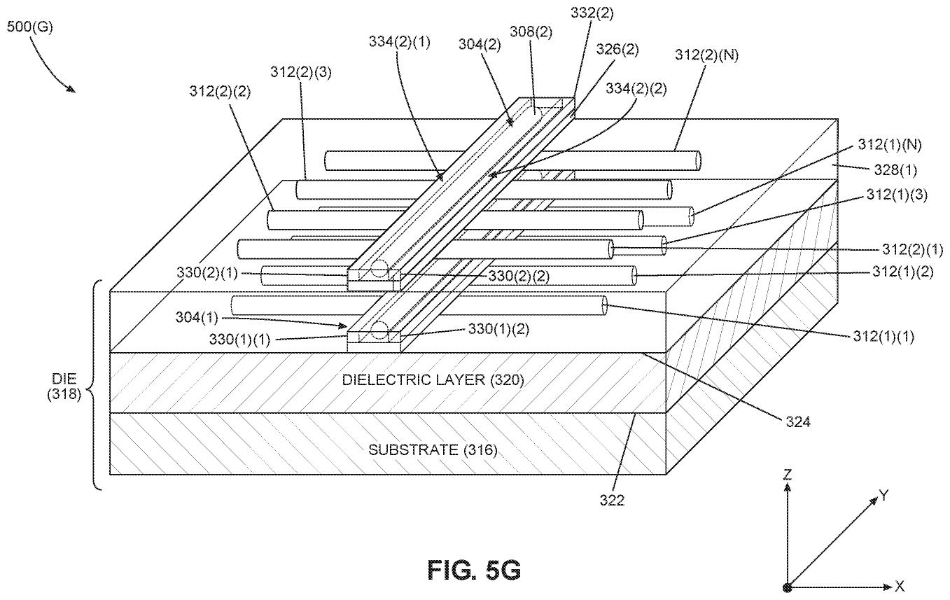

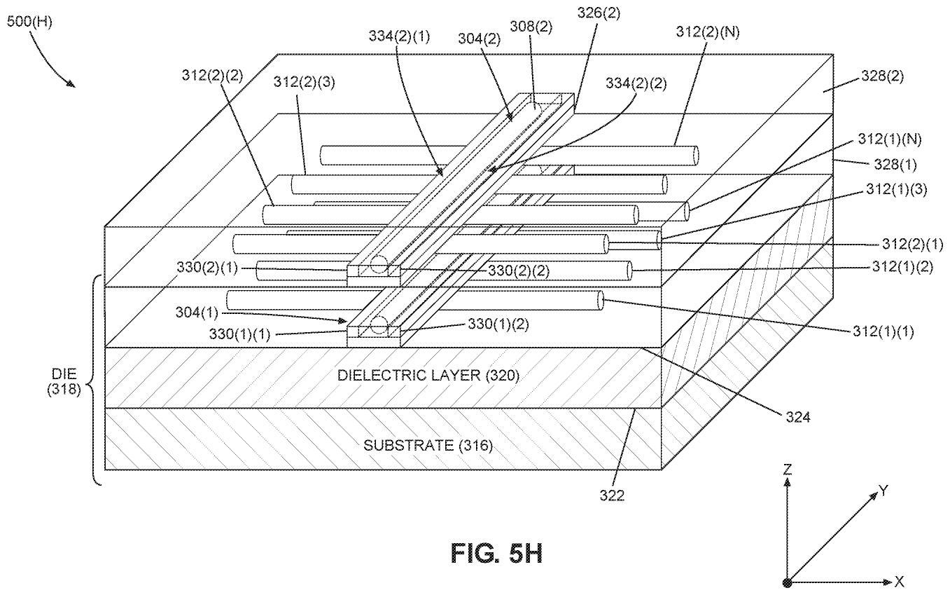

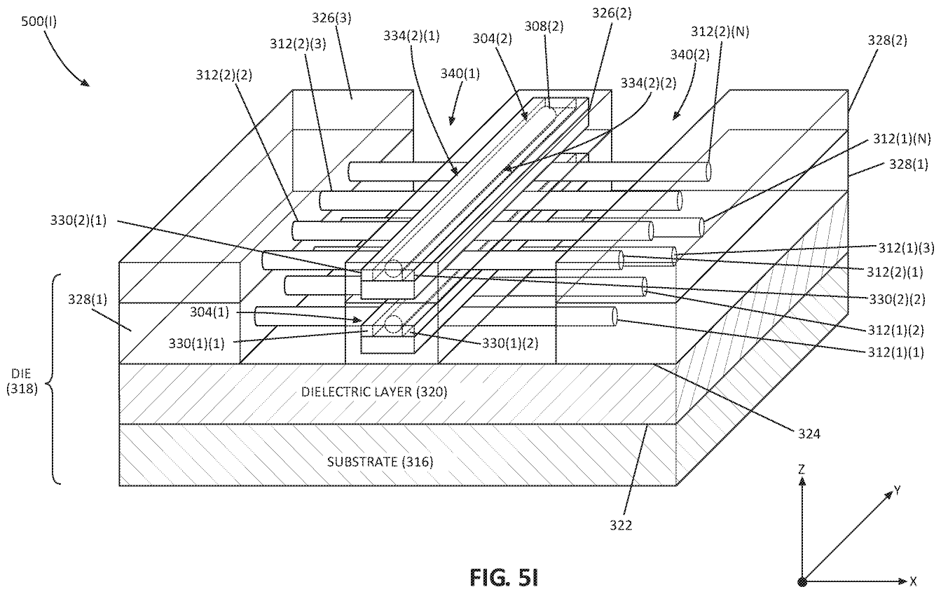

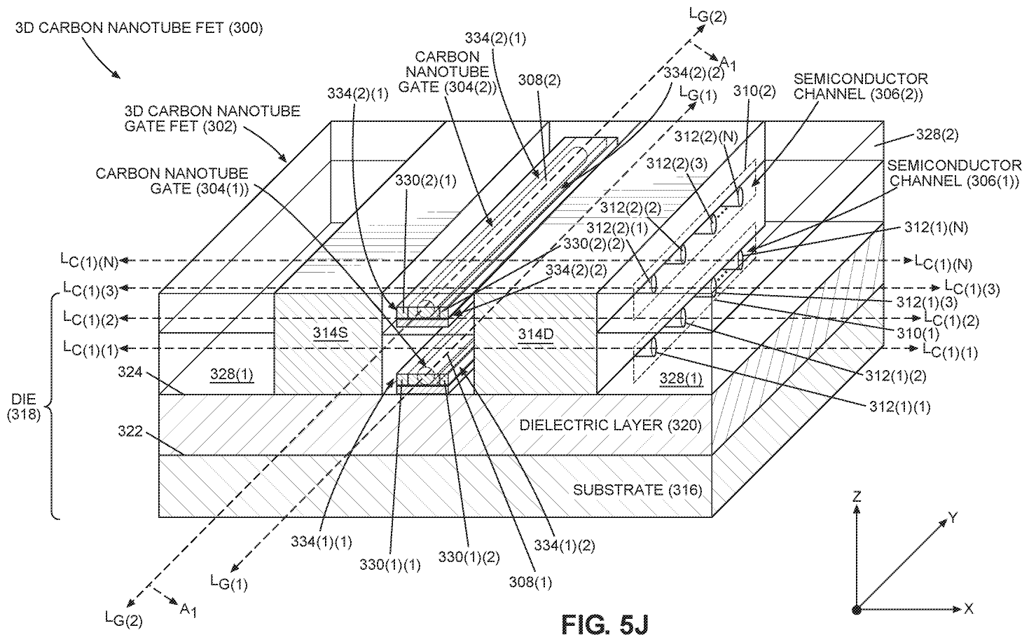

FIG. 4 is a flowchart illustrating an exemplary process 400 of fabricating the 3D carbon nanotube gate FET 302 in FIGS. 3A and 3B. FIGS. 5A-5J illustrate exemplary fabrication stages during the fabrication of the 3D carbon nanotube gate FET 302 in FIGS. 3A and 3B according to the exemplary process 400 in FIG. 4. The exemplary fabrication stages of the 3D carbon nanotube gate FET 302 in FIGS. 5A-5J will be discussed in conjunction with the process 400 in FIG. 4. Common elements between the 3D carbon nanotube gate FET 302 in FIGS. 3A and 3B and the exemplary fabrication stages of the 3D carbon nanotube gate FET 302 in FIGS. 5A-5J are referenced with common element numbers.

In this regard, a first exemplary process step to fabricate the 3D carbon nanotube gate FET 302 in FIGS. 3A and 3B is to dispose the dielectric layer 320 on the top surface 322 of the substrate 316 (block 402 in FIG. 4). This is illustrated in the exemplary fabrication stage 500(A) of the 3D carbon nanotube gate FET 302 in FIG. 5A. As shown therein, the substrate 316 is formed. The substrate may be of a Silicon (Si) material for example. The dielectric layer 320 of a dielectric material is deposited on the top surface 322 of the substrate 316. For example, the dielectric material of the dielectric layer 320 may be an oxide material.

A next step in the exemplary process 400 of fabricating the 3D carbon nanotube gate FET 302 in FIGS. 3A and 3B is to provide the first carbon nanotube channel 306(1). In this regard, the carbon nanotubes 312(1)(1)-312(1)(N) for the carbon nanotube channel structure 310(1) are transferred to a top surface 324 of the dielectric layer 320 (block 404 in FIG. 4). This is illustrated in the exemplary fabrication stage 500(B) of the 3D carbon nanotube gate FET 302 in FIG. 5B. The dielectric layer 320 provides isolation for the carbon nanotube channel structure 310(1). As an example, the carbon nanotubes 312(1)(1)-312(1)(N) may be pre-fabricated off the semiconductor die 318 and then transferred to the top surface 324 of the dielectric layer 320. As shown in FIG. 5B, the carbon nanotubes 312(1)(1)-312(1)(N) are transferred to the top surface 324 of the dielectric layer 320 to be spaced apart by distances D₁ and D₂-D_{N}, which may be the same distance. By transferring the carbon nanotubes 312(1)(1)-312(1)(N) to the dielectric layer 320 as opposed to fabricating the carbon nanotubes 312(1)(1)-312(1)(N) out of a carbon material, a higher density of carbon nanotubes 312(1)(1)-312(1)(N) may be able to be provided in the carbon nanotube channel structure 310(1) and spaced apart by small distances D₁ and D₂-D_{N} than may otherwise be possible for increased drive strength. The carbon nanotubes 312(1)(1)-312(1)(N) may be etched into the pattern that is illustrated in FIG. 5A after transfer using a lithography process of transferring a photoresist layer above the carbon nanotubes 312(1)(1)-312(1)(N), forming a patterned mask above the photoresist layer, and exposing the carbon nanotubes 312(1)(1)-312(1)(N) through openings in the mask to form openings in the photoresist layer for controlling the areas of the carbon nanotubes 312(1)(1)-312(1)(N) to be etched. For example, oxidative etching of the carbon nanotubes 312(1)(1)-312(1)(N) may be performed by successive treatment of carbon nanotubes 312(1)(1)-312(1)(N) with pure ozone or a percentage (e.g., 95% pure) of ozone as an oxidizing agent. Ozone attack on the carbon nanotubes 312(1)(1)-312(1)(N) can occur on the outermost geometric surface of the conglomerate sample of the carbon nanotubes 312(1)(1)-312(1)(N) as a result of the high efficiency of ozone to react in a few collisions with the carbon nanotube 312(1)(1)-312(1)(N) surfaces.

After the lithography and etching process, the carbon nanotubes 312(1)(1)-312(1)(N) are disposed on the dielectric layer 320 of respective lengths L₁, L₂, and L₃-L_{N}. The lengths L₁, L₂, and L₃-L_{N} of the carbon nanotubes 312(1)(1)-312(1)(N) may be the same length and of a length sufficient to leave end portions of the carbon nanotubes 312(1)(1)-312(1)(N) exposed from the carbon nanotube gate 304(1) (see FIGS. 3A and 3B) to form a source and drain in contact with such end portions as will be described below.

A next step in the exemplary process 400 of fabricating the 3D carbon nanotube gate FET 302 in FIGS. 3A and 3B is to dispose a channel dielectric layer 326(1) over the carbon nanotubes 312(1)(1)-312(1)(N) to insulate the carbon nanotubes 312(1)(1)-312(1)(N) (block 406 in FIG. 4). The carbon nanotube 308(1) of the carbon nanotube gate 304(1) (see FIGS. 3A and 3B) is the transferred above the carbon nanotubes 312(1)(1)-312(1)(N) between the carbon nanotubes 312(1)(1)-312(1)(N) and the channel dielectric layer 326(1). This is illustrated in the exemplary fabrication stage 500(C) of the 3D carbon nanotube gate FET 302 in FIG. 5C. In this regard, as shown in FIG. 5C, the channel dielectric layer 326(1) forms around at least a portion of the carbon nanotubes 312(1)(1)-312(1)(N), such as shown in FIGS. 3A and 3B. The carbon nanotube 308(1) for the carbon nanotube gate 304(1) is then transferred to the channel dielectric layer 326(1) along the longitudinal axis L_{G(1)} (block 408 in FIG. 4). As an example, the carbon nanotube 308(1) may be pre-fabricated off the semiconductor die 318 and then transferred to the channel dielectric layer 326(1). The carbon nanotube 308(1) may be etched into the pattern that is illustrated in FIG. 5A after transfer using a lithography process of transferring a photoresist layer above the channel dielectric layer 326(1), forming a patterned mask above the photoresist layer, and exposing the carbon nanotube 308(1) through openings in the mask to form openings in the photoresist layer for controlling the areas of the carbon nanotube 308(1) may to be etched. After the lithography and etching process, the carbon nanotube 308(1) is disposed on the dielectric layer 320 of length L₍₁₎. The length L₍₁₎ of the carbon nanotube 308(1) is sufficient to overlap the entire carbon nanotube channel structure 310(1) in a direction of the longitudinal axis L_{G(1)} for improved channel control.

A next step in an exemplary process of fabricating the 3D carbon nanotube gate FET 302 in FIGS. 3A and 3B is to deposit a film layer 332(1) above the carbon nanotube 308(1) and etch the film layer 332(1) and the channel dielectric layer 326(1) so that spacers 330(1)(1), 330(1)(2) can be formed at a first gate side 334(1)(1) and a second gate side 334(1)(2) of the carbon nanotube 308(1) of the carbon nanotube gate 304(1). This is shown in the exemplary fabrication stage 500(D) of 3D carbon nanotube gate FET 302 in FIG. 5D. The film layer 332(1) and the channel dielectric layer 326(1) can be etched through a photolithography and etch process to form the spacers 330(1)(1), 330(1)(2). The etching of the film layer 332(1) and channel dielectric layer 326(1) forms the spacers 330(1)(1), 330(1)(2) on the first gate side 334(1)(1) of the carbon nanotube 308(1) extending in the direction (Y-axis) of the longitudinal axis L_{G(1)} and a second gate side 334(1)(2) opposite the first gate side 334(1)(1) extending in the direction (Y-axis) of the second longitudinal axis L_{G(1)}. The etching of the film layer 332(1) and channel dielectric layer 326(1) also leaves first end portions 336(1)-336(N) and second end portions 338(1)-338(N) of the carbon nanotubes 312(1)(1)-312(1)(N) of the carbon nanotube channel structure 310(1) extending beyond the carbon nanotube gate 304(1) in the direction (X-axis) of the longitudinal axes L_{C(1)}-L_{C(N)} axes to later form the source 314S and the drain 314D in contact with the first end portions 336(1)-336(N) and second end portions 338(1)-338(N) of the carbon nanotubes 312(1)(1)-312(1)(N) as shown in FIGS. 3A and 3B. For example, the film layer 332(1) may be a Silicon Nitride (SiN) layer.

A next step in the exemplary process 400 of fabricating the 3D carbon nanotube gate FET 302 in FIGS. 3A and 3B is to dispose an interlayer dielectric 328(1) above and on the carbon nanotubes 312(1)(1)-312(1)(N) to insulate the carbon nanotubes 312(1)(1)-312(1)(N) (block 410 in FIG. 4). This is illustrated in the exemplary fabrication stage 500(E) of the 3D carbon nanotube gate FET 302 in FIG. 5E.

As discussed above and illustrated in the 3D carbon nanotube gate FET 302 in FIGS. 3A and 3B, a second carbon nanotube channel structure 310(2) and carbon nanotube gate 304(2) can optionally be formed above the first carbon nanotube channel structure 310(1) and carbon nanotube gate 304(1) to increase drive strength of the 3D carbon nanotube gate FET 302. In this manner, additional carbon nanotube channel structures and carbon nanotube gates can be formed in layers on top of each other in the semiconductor die 318 to make efficient use of chip area in the vertical direction (Z-axis direction).

In this regard, the second carbon nanotubes 312(2)(1)-312(2)(N) for the second carbon nanotube channel structure 310(2) can transferred to a top surface 339 of the second channel dielectric layer 326(2). This is illustrated in the exemplary fabrication stage 500(E) of the 3D carbon nanotube gate FET 302 in FIG. 5E. The details of transferring the second carbon nanotubes 312(2)(1)-312(2)(N) for the second carbon nanotube channel structure 310(2) on the second channel dielectric layer 326(2) can be the same as transferring the first carbon nanotubes 312(1)(1)-312(1)(N) for the first carbon nanotube channel structure 310(1) on the first dielectric layer 320 discussed above with regard to fabrication stage 500(B) in FIG. 5B.

A next step in an exemplary process of fabricating the 3D carbon nanotube gate FET 302 in FIGS. 3A and 3B is to dispose the second channel dielectric layer 326(2) over the carbon nanotubes 312(2)(1)-312(2)(N) to insulate the carbon nanotubes 312(2)(1)-312(2)(N). The carbon nanotube 308(2) of the carbon nanotube gate 304(2) is the transferred above the carbon nanotubes 312(2)(1)-312(2)(N) between the carbon nanotubes 312(2)(1)-312(2)(N) and the second channel dielectric layer 326(2). This is illustrated in the exemplary fabrication stage 500(F) of the 3D carbon nanotube gate FET 302 in FIG. 5F. The details of transferring the second channel dielectric layer 326(2) over the carbon nanotubes 312(2)(1)-312(2)(N) and the second carbon nanotube 308(2) for the second carbon nanotube gate 304(2) can be the same as transferring the first channel dielectric layer 326(1) over the carbon nanotubes 312(1)(1)-312(1)(N) and the first carbon nanotube 308(1) for the first carbon nanotube gate 304(1) discussed above with regard to fabrication stage 500(C) in FIG. 5C.

A next step in an exemplary process of fabricating the 3D carbon nanotube gate FET 302 in FIGS. 3A and 3B is to deposit a second channel dielectric layer 326(2) and a second film layer 332(2) above the second carbon nanotube 308(2) and etch the second film layer 332(2) and the second channel dielectric layer 326(2) so that second spacers 330(2)(1), 330(2)(2) can be formed at a first gate side 334(2)(1) and a second gate side 334(2)(2) of the second carbon nanotube 308(2) of the carbon nanotube gate 304(2). This is shown in the exemplary fabrication stage 500(G) of the 3D nanotube gate FET 302 in FIG. 5G. The details of depositing the second film layer 332(2) above the second carbon nanotube 308(2) and etching the second film layer 332(2) and the second channel dielectric layer 326(2) can be the same as depositing the first film layer 332(1) above the first carbon nanotube 308(1) and etching the first film layer 332(1) and the first channel dielectric layer 326(1) discussed above with regard to fabrication stage 500(D) in FIG. 5D.

A next step in an exemplary process of fabricating the 3D carbon nanotube gate FET 302 in FIGS. 3A and 3B is to dispose a second interlayer dielectric 328(2) above and on the second carbon nanotubes 312(2)(1)-312(2)(N) to insulate the carbon nanotubes 312(2)(1)-312(2)(N). This is illustrated in the exemplary fabrication stage 500(H) of the 3D carbon nanotube gate FET 302 in FIG. 5H.

A next step in an exemplary process of fabricating the 3D carbon nanotube gate FET 302 in FIGS. 3A and 3B is to form the source 314S and the drain 314D in contact with the first and second end portions 336(1)-336(N), 338(1)-338(N) of the carbon nanotubes 312(1)(1)-312(1)(N), 312(2)(1)-312(2)N. This is illustrated in the exemplary fabrication stage 500(I) of the 3D carbon nanotube gate FET 302 in FIG. 5I. As shown therein, a lithography and etching process has been performed to etch the second and third dielectric layers 326(2), 326(3) above the first and second end portions 334(1)(1), 334(1)(2), 334(2)(1), 334(2)(2) of the carbon nanotubes 312(1)(1)-312(1)(N), 312(2)(1)-312(2)(N). Openings 340(1), 340(2) are formed above the first and second end portions 334(1)(1), 334(1)(2), 334(2)(1), 334(2)(2) of the carbon nanotubes 312(1)(1)-312(1)(N), 312(2)(1)-312(2)(N). Then, as shown in the exemplary fabrication stage 500(J) of the 3D carbon nanotube gate FET 302 in FIG. 5J, fill materials for the source 314S and drain 314D are filled in the openings 340(1), 340(2) and come into contact with and surround the carbon nanotubes 312(1)(1)-312(1)(N), 312(2)(1)-312(2)(N).

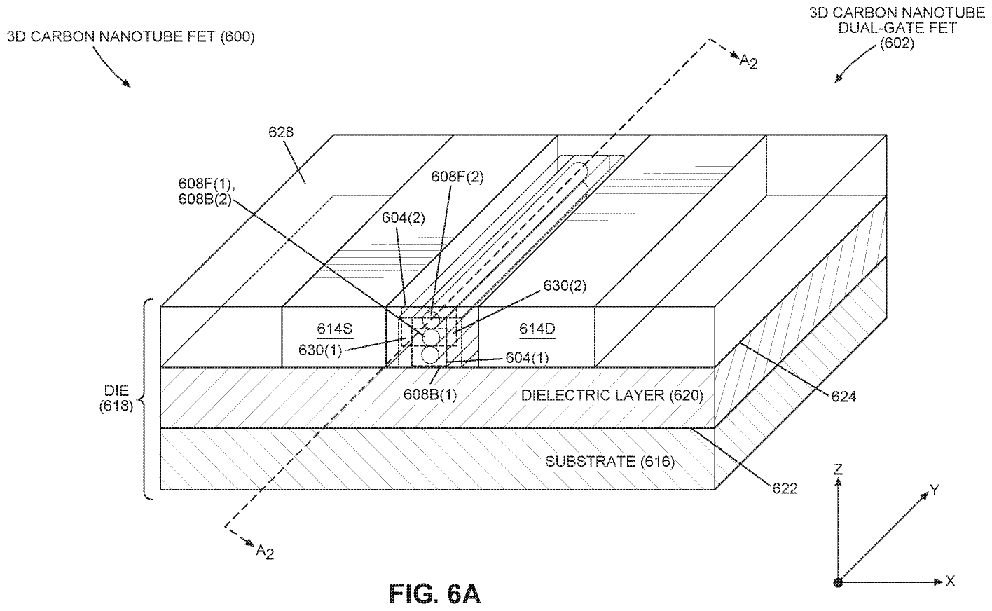

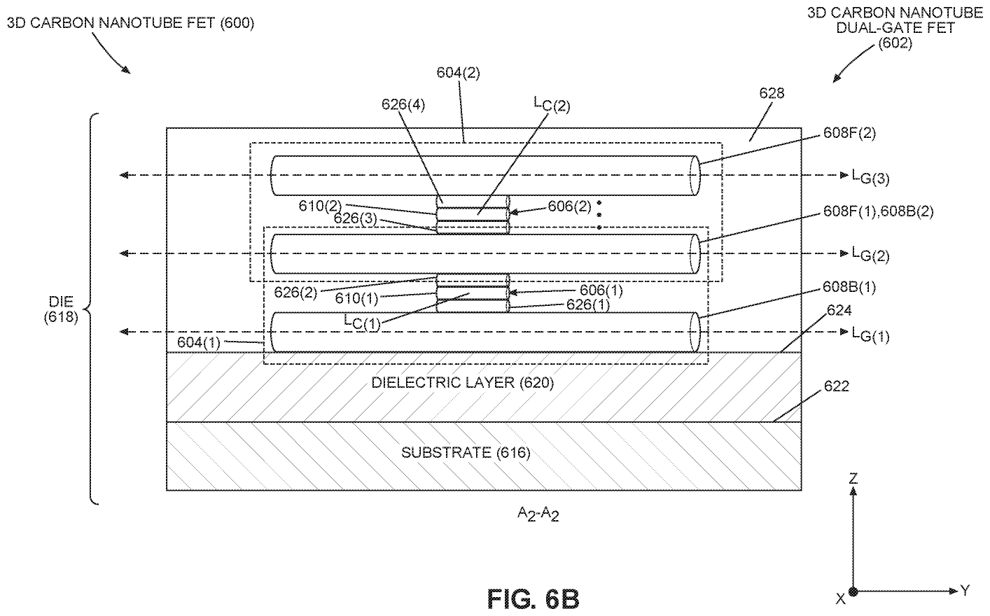

Other 3D FET structures can be formed that employ a carbon nanotube structure as a gate. In this regard, FIGS. 6A and 6B are front perspective and side views, respective of an exemplary 3D carbon nanotube FET 600 in the form of a 3D carbon nanotube dual-gate FET 602. FIG. 6B is shown along the cross-sectional line A₂-A₂ in FIG. 6A. The 3D carbon nanotube dual-gate FET 602 in this example includes dual carbon nanotube gate 604(1), 604(2) that each include a respective back carbon nanotube gate 608B(1), 608B(2) and a front carbon nanotube gate 608F(1), 608F(2). The carbon nanotube gates 604(1) includes the back carbon nanotube gate 608B(1) and the front carbon nanotube gate 608F(1). The carbon nanotube gate 604(2) includes the back carbon nanotube gate 608B(2) the front carbon nanotube gate 608F(2) in this example. The front carbon nanotube gate 608F(1) and the back carbon nanotube gate 608B(2) are the same carbon nanotube in this example. As will be discussed in more detail bellow, the carbon nanotube gates 604(1), 604(2) are disposed adjacent to respective semiconductor channels. In this example, the carbon nanotube gates 604(1), 604(2) are disposed around at least a portion of respective raised semiconductor channels 606(1), 606(2) that each comprise a semiconductor channel structure 610(1), 610(2) as shown in FIG. 6B to form a 3D FET structure. The carbon nanotube gates 604(1), 604(2) control or permit electrons to flow through or block their passage between a source 614S and a drain 614D by creating or eliminating a channel through the semiconductor channel structures 610(1), 610(2) of the semiconductor channels 606(1), 606(2) based on a voltage applied to the carbon nanotube gates 604(1), 604(2). In this example, including the dual carbon nanotube gates 604(1), 604(2) and semiconductor channel structures 610(1), 610(2) can increase the drive strength of the 3D carbon nanotube gate FET 602 as opposed to use of a single carbon nanotube gate controlling a semiconductor channel structure.

With continuing reference to FIGS. 6A and 6B, in this example, the 3D carbon nanotube gate FET 602 includes a substrate 616, which may be a Silicon (Si) material layer for example. The substrate 616 is part of a semiconductor die 618 (shown as “die 618” in FIGS. 6A and 6B). A dielectric layer 620 composed of a dielectric material is disposed on a top surface 622 of the substrate 616 to insulate the source 614S, the drain 614D, and the back carbon nanotube gate 608B(1) from adjacent devices formed on the substrate 616 in another area of the semiconductor die 618. The back carbon nanotube gate 608B(1) is disposed above the dielectric layer 620, and on a top surface 624 of the dielectric layer 620 in this example. As shown in FIG. 6B, each back and front carbon nanotube gate 608B(1), 608F(1), 608B(2), 608F(2) is disposed along a longitudinal axis L_{G(1)}-L_{G(3)} disposed in a first direction (Y-axis direction in FIG. 6B) that are substantially parallel to each other. The back and front carbon nanotube gates 608B(1), 608F(1), 608B(2), 608F(2) are a sheet of carbon atoms, such as a graphene sheet, formed in a cylindrical shape thereby forming an internal hollow structure. The thickness of the outer walls of the back and front carbon nanotube gates 608B(1), 608F(1), 608B(2), 608F(2) may be 5 nanometers (nm) or less as an example. The back and front carbon nanotube gates 608B(1), 608F(1), 608B(2), 608F(2) are spaced apart, but such placement is not limited to a fabrication limitation such that the back and front carbon nanotube gates 608B(1), 608F(1), 608B(2), 608F(2) can be pre-fabricated and transferred to the semiconductor die 618 instead of being fabricated in the semiconductor die 618. This allows more back and front carbon nanotube gates 608B(1), 608F(1), 608B(2), 608F(2) to be included in the carbon nanotube gates 604(1), 604(2) to increase drive strength. An interlayer dielectric 628 is disposed over the back and front carbon nanotube gates 608B(1), 608F(1), 608B(2), 608F(2).

As shown in FIG. 6B, a first channel dielectric layer 626(1) comprised of a dielectric material, such as a high-K dielectric material, is disposed above and on the back carbon nanotube gate 608B(1) to insulate the back carbon nanotube gate 608B(1) from a semiconductor channel structure 610(1). The semiconductor channel structure 610(1) can be a semiconductor material, which may include without limitation a monolayer transition metal, such as dichalcogenide (MX2), i.e., Molybdenum Disulfide (MoS₂), Molybdenum Diselenide (MoSe₂), Molybdenum Ditellurium (MoTe₂), Tungsten Disulfide (WS₂), Tungsten Diselenide (WSe₂), and Tin Disulfide (SnS₂). The thickness of the first channel dielectric layer 626(1) may be half or less of the thickness of the outer walls of the back and front carbon nanotube gates 608B(1), 608F(1), 608B(2), 608F(2) as an example. Examples of materials of the first channel dielectric layer 626(1) include Hafnium Oxide (HfOx), Hafnium Silicon Oxide (HfSiOx), and Hafnium Silicon Oxygen Nitride (HfON). The semiconductor channel structures 610(1), 610(2) that form the respective semiconductor channels 606(1), 606(2) have longitudinal axes L_{C(1)}, L_{C(2)} extending in a second direction (X-axis direction in FIG. 6B) substantially orthogonal to the longitudinal axes L_{G(1)}-L_{G(3)} of the back and front carbon nanotube gates 608B(1), 608F(1), 608B(2), 608F(2).

As shown in FIG. 6B, in this example, a second channel dielectric layer 626(2) is formed above the semiconductor channel structure 610(1) to also insulate the front carbon nanotube gate 608F(1) from the semiconductor channel structure 610(1). In this manner, the back and front carbon nanotube gates 608B(1), 608F(1) provide the dual carbon nanotube gate 604(1) to control carrier mobility in the semiconductor channel structure 610(1) disposed between the back and front carbon nanotube gates 608B(1), 608F(1). Likewise, a third channel dielectric layer 626(3) is formed above the back carbon nanotube gate 608B(2) to insulate the semiconductor channel structure 610(2) from the back carbon nanotube gate 608B(2). A fourth channel dielectric layer 626(4) is also formed above the semiconductor channel structure 610(2) to insulate the semiconductor channel structure 610(2) from the front carbon nanotube gate 608F(2). In this manner, the back and front carbon nanotube gates 608B(2), 608F(2) provide another dual carbon nanotube gate 604(2) to control carrier mobility in the semiconductor channel structure 610(2) disposed between the back and front carbon nanotube gates 608B(2), 608F(2). The second, third, and fourth channel dielectric layers 626(2), 626(3), 626(4) are comprised of a dielectric material, such as a high-K dielectric material. Spacers 630(1), 630(2) are formed on opposite sides of the back and front carbon nanotube gates 608B(1), 608F(1), 608B(2), 608F(2) as shown in FIG. 6A for insulation of the back and front carbon nanotube gates 608B(1), 608F(1), 608B(2), 608F(2).

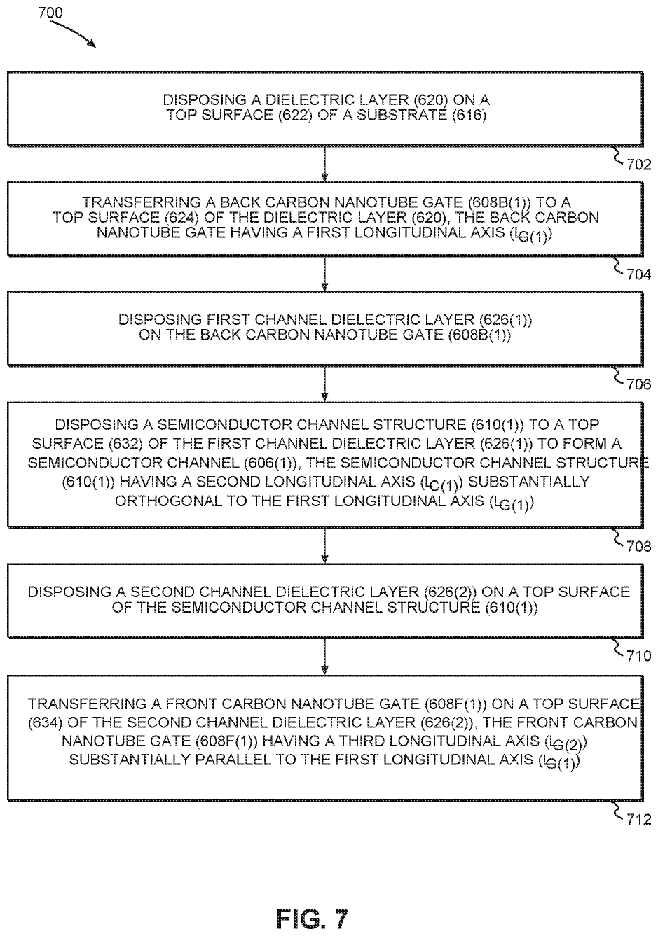

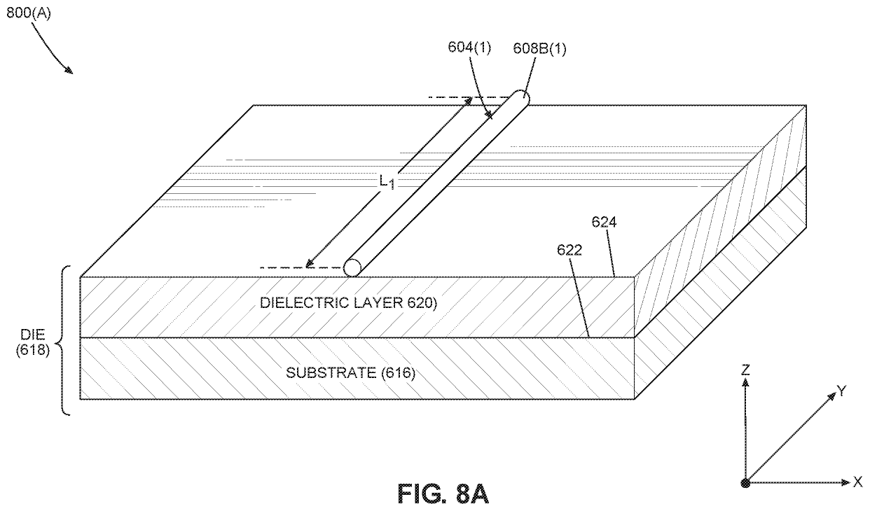

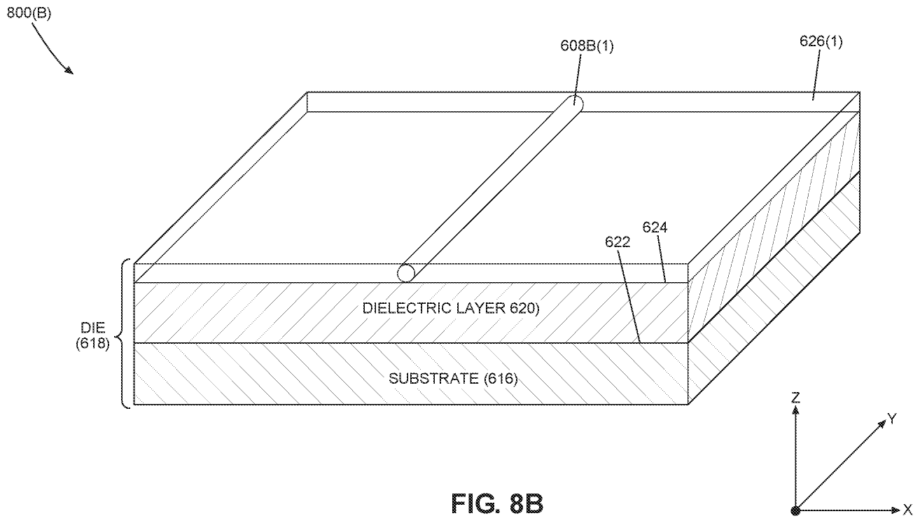

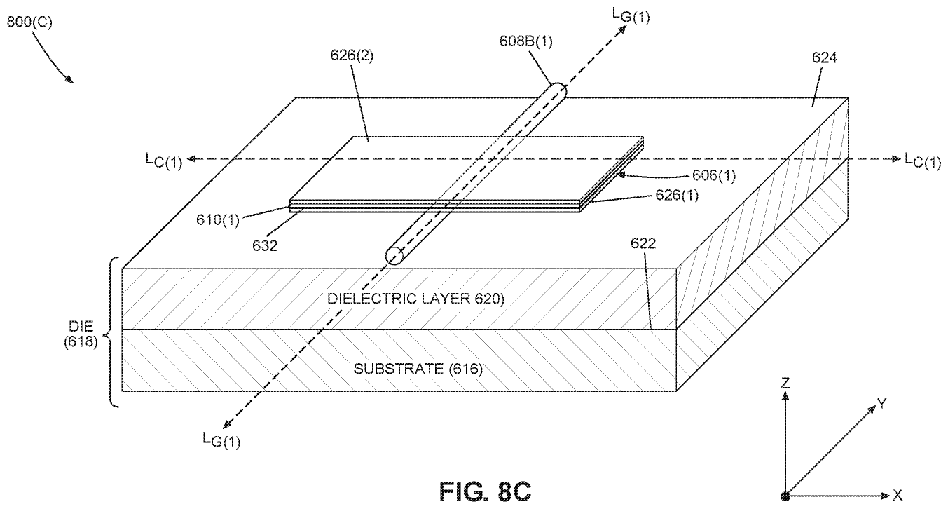

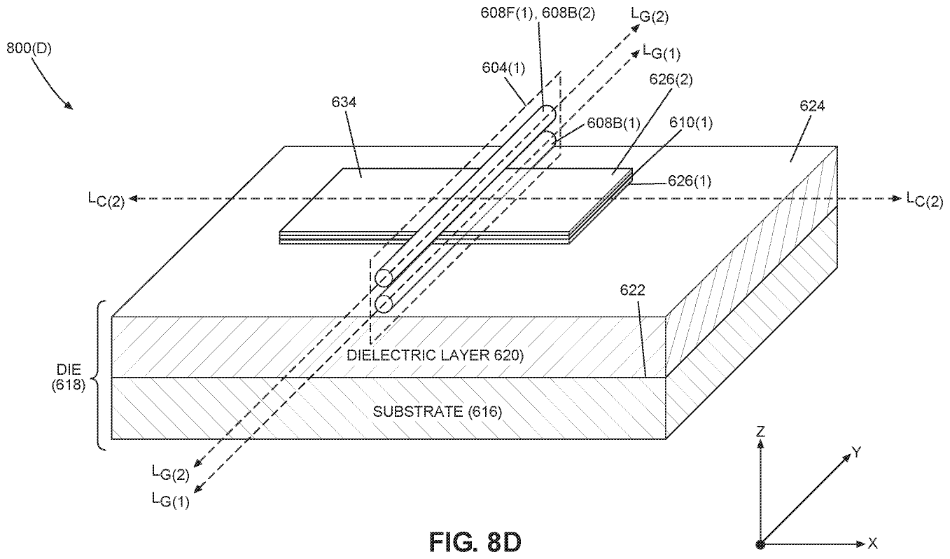

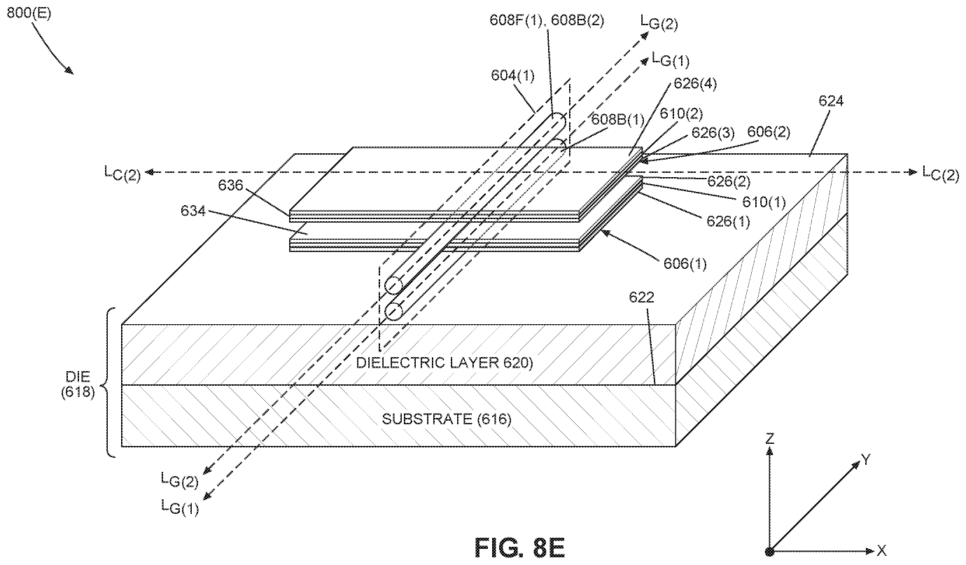

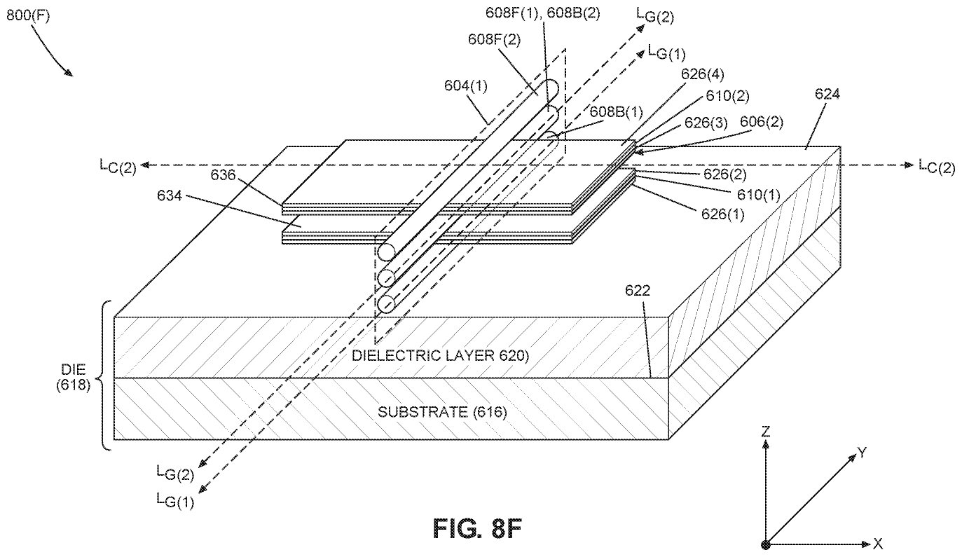

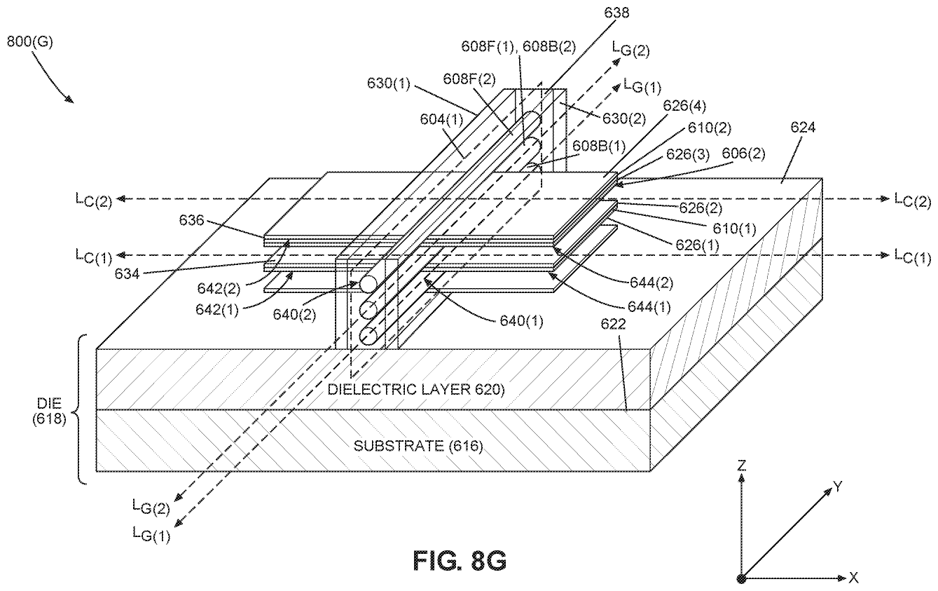

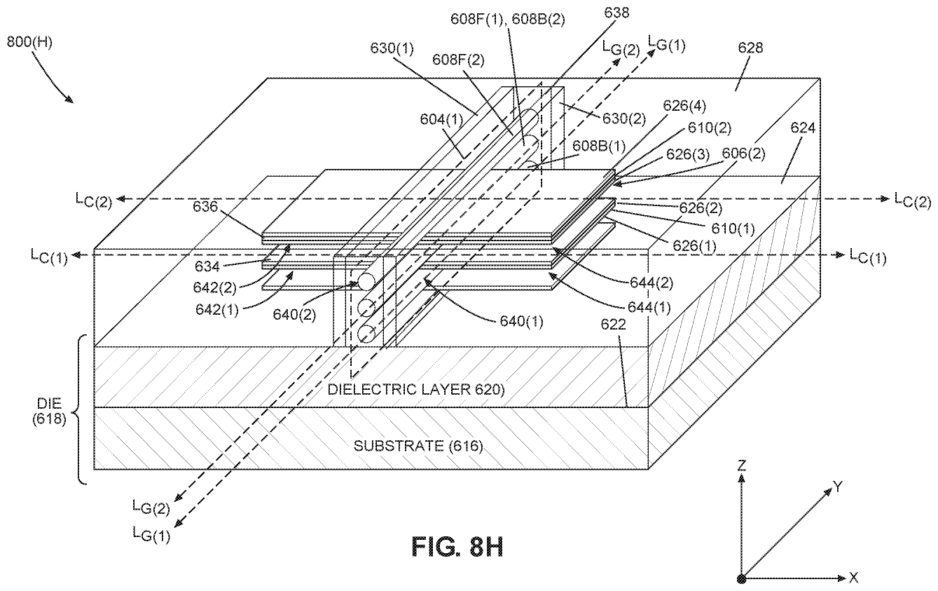

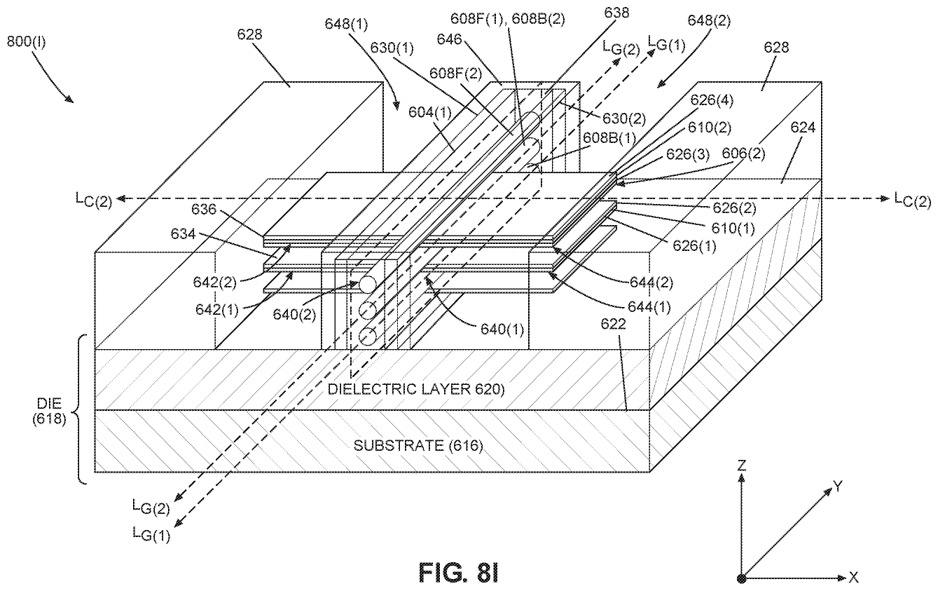

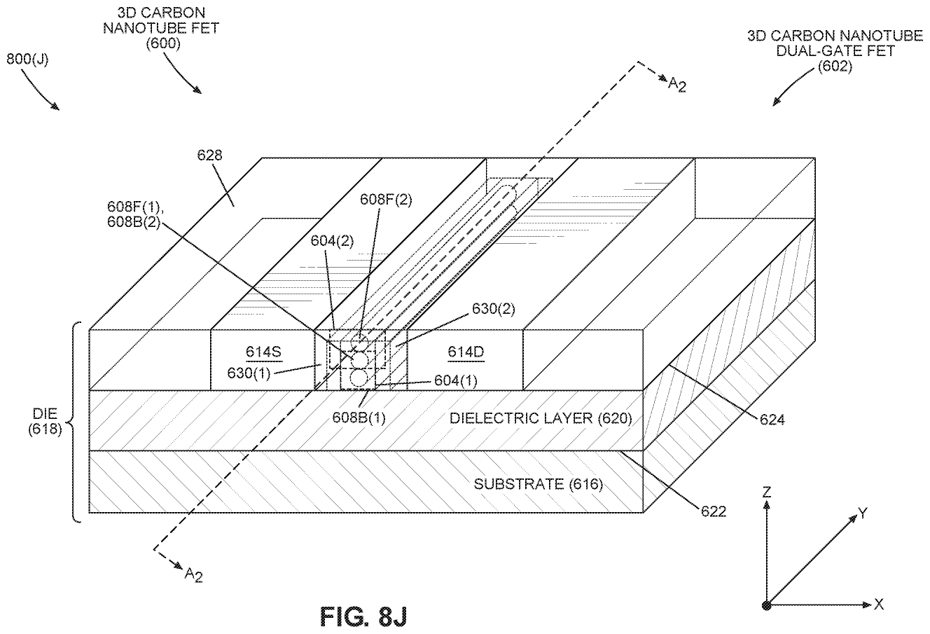

FIG. 7 is a flowchart illustrating an exemplary process 700 of fabricating the 3D carbon nanotube dual-gate FET 602 in FIGS. 6A and 6B. FIGS. 8A-8J illustrate exemplary fabrication stages during the fabrication of the 3D carbon nanotube dual-gate FET 602 in FIGS. 6A and 6B according to the exemplary process 700 in FIG. 7. The exemplary fabrication stages of the 3D carbon nanotube dual-gate FET 602 in FIGS. 8A-8J will be discussed in conjunction with the process 700 in FIG. 7. Common elements between the 3D carbon nanotube dual-gate FET 602 in FIGS. 6A and 6B and the exemplary fabrication stages of the 3D carbon nanotube dual-gate FET 602 in FIGS. 8A-8J are referenced with common element numbers.

In this regard, a first exemplary process step to fabricate the 3D carbon nanotube gate FET 602 in FIGS. 6A and 6B is to dispose the dielectric layer 620 on the top surface 622 of the substrate 616 (block 702 in FIG. 7). This is illustrated in the exemplary fabrication stage 800(A) of the 3D carbon nanotube gate FET 602 in FIG. 8A. As shown therein, the substrate 616 is formed. The substrate 616 may be of a Silicon (Si) material for example. The dielectric layer 620 of a dielectric material is deposited on the top surface 622 of the substrate 616. For example, the dielectric material of the dielectric layer 620 may be an oxide material. A next step in the exemplary process 700 of fabricating the 3D carbon nanotube gate FET 602 in FIGS. 6A and 6B is to provide a back carbon nanotube gate 608B(1) of the first carbon nanotube gate 604(1). This is illustrated in the exemplary fabrication stage 800(A) of the 3D carbon nanotube gate FET 602 in FIG. 8A. In this regard, the back carbon nanotube gate 608B(1) for the first carbon nanotube gate 604(1) is transferred to a top surface 624 of the dielectric layer 620 (block 702 in FIG. 7). This is also illustrated in the exemplary fabrication stage 800(B) of the 3D carbon nanotube gate FET 602 in FIG. 8B. The dielectric layer 620 provides isolation for the back carbon nanotube gate 608B(1). As an example, the back carbon nanotube gate 608B(1) may be pre-fabricated off the semiconductor die 618 and then transferred to the top surface 624 of the dielectric layer 620. The back carbon nanotube gate 608B(1) may be etched into the pattern that is illustrated in FIG. 8A after transfer using a lithography process of transferring a photoresist layer above the back carbon nanotube gate 608B(1), forming a patterned mask above the photoresist layer, and exposing the back carbon nanotube gate 608B(1) through openings in the mask to form openings in the photoresist layer for controlling the areas of the back carbon nanotube gate 608B(1), to be etched. For example, oxidative etching of the back carbon nanotube gate 608B(1), may be performed by successive treatment of back carbon nanotube gate 608B(1), with pure ozone or a percentage (e.g., 95% pure) of ozone as an oxidizing agent. Ozone attack on the back carbon nanotube gate 608B(1) can occur on the outermost geometric surface of the conglomerate sample of the back carbon nanotube gate 608B(1), as a result of the high efficiency of ozone to react in a few collisions with the back carbon nanotube gate 608B(1) surface. A high-K dielectric material 626(1) is also disposed over the back carbon nanotube gate 608B(1).

A next step in the exemplary process 700 of fabricating the 3D carbon nanotube gate FET 702 in FIGS. 6A and 6B is to dispose a channel dielectric layer 626(1) over the back carbon nanotube gate 608B(1) to insulate the back carbon nanotube gate 608B(1) as shown in FIG. 8B (block 706 in FIG. 7). The semiconductor channel structure 610(1) of the semiconductor channel 606(1) is then formed above the back carbon nanotube gate 608B(1) (block 708 in FIG. 7). This is illustrated in the exemplary fabrication stage 800(C) of the 3D carbon nanotube gate FET 302 in FIG. 8C. In this regard, as shown in FIG. 8C, the channel dielectric layer 626(1) forms around at least a portion of the back carbon nanotube gate 608B(1). The semiconductor channel structure 610(1), for example a transition metal, is formed a top surface 632 of the first channel dielectric layer 626(1) to form the semiconductor channel 606(1). The semiconductor channel structure 610(1) has a second longitudinal axis L_{C(1)} substantially orthogonal to the first longitudinal axis L_{G(1)} of the back carbon nanotube gate 608B(1). A second channel dielectric layer 626(2) is formed over the semiconductor channel structure 610(1) (block 710 in FIG. 7). In this manner, the semiconductor channel structure 610(1) is insulated from the back carbon nanotube gate 608B(1) and will be insulated from a later formed front carbon nanotube gate 608F(1) formed on the second channel dielectric layer 626(2). The first and second channel dielectric layers 626(1), 626(2) and the semiconductor channel structure 610(1) are shown as having been etched through a photolithography and etch process.

A next step in an exemplary process of fabricating the 3D carbon nanotube gate FET 602 in FIGS. 6A and 6B is to provide the front carbon nanotube gate 608F(1). This is illustrated in the exemplary fabrication stage 800(D) of the 3D carbon nanotube gate FET 602 in FIG. 8D. In this regard, the front carbon nanotube gate 608F(1) for the first carbon nanotube gate 604(1) is transferred to a top surface 634 of the second channel dielectric layer 626(2) (block 712 in FIG. 7). This is also illustrated in the exemplary fabrication stage 800(D) of the 3D carbon nanotube gate FET 602 in FIG. 8D. The front carbon nanotube gate 608F(1) may be etched into the pattern that is illustrated in FIG. 8D after transfer using a lithography process of transferring a photoresist layer above the front carbon nanotube gate 608F(1), forming a patterned mask above the photoresist layer, and exposing the front carbon nanotube gate 608F(1) through openings in the mask to form openings in the photoresist layer for controlling the areas of the front carbon nanotube gate 608F(1), to be etched.

More than one carbon nanotube dual-gate 604 may be formed in the 3D carbon nanotube gate FET 602, as shown in FIGS. 6A and 6B. In this regard, a next step in the exemplary process 700 of fabricating the 3D carbon nanotube gate FET 602 in FIGS. 6A and 6B can be to provide a third channel dielectric layer 626(3) above and on the front carbon nanotube gate 608F(1) to provide insulation between the front carbon nanotube gate 608F(1) and another semiconductor channel that the front carbon nanotube gate 608F(1) may control. As discussed above, the front carbon nanotube gate 608F(1) can also serve as a second back nanotube gate 608B(2) to control another semiconductor channel. This is illustrated in the exemplary fabrication stage 800(E) of the 3D carbon nanotube gate FET 602 in FIG. 8E. In this regard, as shown in FIG. 8E, the third channel dielectric layer 626(3) forms around at least a portion of the front carbon nanotube gate 608F(1). A second semiconductor channel structure 610(2) is formed a top surface 636 of the third channel dielectric layer 626(3) to form the second semiconductor channel 606(2). The second semiconductor channel structure 610(2) has a second longitudinal axis L_{C(2)} substantially orthogonal to the first longitudinal axis L_{G(1)} of the front carbon nanotube gate 608F(1). A fourth channel dielectric layer 626(4) is formed over the second semiconductor channel structure 610(2). In this manner, the second semiconductor channel structure 610(2) is insulated from the front carbon nanotube gate 608F(1) and the back carbon nanotube gate 608B(2) and will be insulated from a second front carbon nanotube gate 608F(2) formed on the fourth channel dielectric layer 626(4), shown in the fabrication stage 800(F) in FIG. 8F. The third and fourth channel dielectric layers 626(3), 626(4) and the second semiconductor channel structure 610(2) are shown as having been etched through a photolithography and etch process.

A next exemplary process of fabricating the 3D carbon nanotube gate FET 602 in FIGS. 6A and 6B is to deposit a film layer 638 over the back and front carbon nanotube gates 608B(1), 608F(1), 608B(2), 608F(2) and semiconductor channel structures 610(1), 610(2) and etch the film layer 638 so that spacers 630(1), 630(2) can be formed at a first gate side 640(1) and a second gate side 640(2) of back and front carbon nanotube gates 608B(1), 608F(1), 608B(2), 608F(2). This is shown in the exemplary fabrication stage 800(G) of the nanotube gate FET 302 in FIG. 8G. For example, the film layer 638 may be a Silicon Nitride (SiN) layer. The film layer 638 can be etched through a photolithography and etch process to form the spacers 630(1), 630(2). The etching of the film layer 638 on the first gate side 640(1) of the back and front carbon nanotube gates 608B(1), 608F(1), 608B(2), 608F(2) extending in the direction (Y-axis) of the longitudinal axis L_{G(1)} and the second gate side 640(2) of the back and front carbon nanotube gates 608B(1), 608F(1), 608B(2), 608F(2) opposite the first gate side 640(1) extending in the direction (Y-axis) of the second longitudinal axis L_{G(2)}. The etching of the film layer 638 also leaves first end portions 642(1), 642(2) and second end portions 644(1), 644(2) of the semiconductor channel structures 610(1), 610(2) extending beyond the back and front carbon nanotube gates 608B(1), 608F(1), 608B(2), 608F(2) in the direction (X-axis) of the longitudinal axes L_{C(1)}-L_{C(2)} axes to later form the source 614S and the drain 614D in contact with the first end portions 642(1), 642(2) and the second end portions 644(1), 644(2) the semiconductor channel structures 610(1), 610(2).

A next step in an exemplary process of fabricating the 3D carbon nanotube gate FET 602 in FIGS. 6A and 6B is to dispose another interlayer dielectric 628 above the back and front carbon nanotube gates 608B(1), 608F(1), 608B(2), 608F(2) and semiconductor channel structures 610(1), 610(2) to insulate the back and front carbon nanotube gates 608B(1), 608F(1), 608B(2), 608F(2) and semiconductor channel structures 610(1), 610(2) from structures formed in higher layers of the semiconductor die 618. This is illustrated in the exemplary fabrication stage 800(H) of the 3D carbon nanotube gate FET 602 in FIG. 8H.

A next step in an exemplary process of fabricating the 3D carbon nanotube gate FET 602 in FIGS. 6A and 6B is to form the source 614S and the drain 614D in contact with the first and second end portions 642(1),642(2) and 644(1), 644(2) of the semiconductor channel structures 610(1), 610(2). This is illustrated in the exemplary fabrication stage 800(I) of the 3D carbon nanotube gate FET 602 in FIG. 8I. As shown therein, a lithography and etching process has been performed to etch the dielectric layer 646. Openings 648(1), 648(2) are formed above the first and second end portions 642(1), 642(2) and 644(1), 644(2) of the semiconductor channel structures 610(1), 610(2). Then, as shown in a next the exemplary fabrication stage 800(J) of the 3D carbon nanotube gate PET 602 in FIG. 8J, fill materials for the source 614S and drain 614D are filled in the openings 648(1), 648(2) and come into contact with and surround the first and second end portions 642(1), 642(2) and 644(1), 644(2) of the semiconductor channel structures 610(1), 610(2).

Carbon nanotube gate FETs, including but not limited to the 3D carbon nanotube gate FET 302 in FIGS. 3A and 3B, and the 3D carbon nanotube dual-gate FET 602 in FIGS. 6A and 6B, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

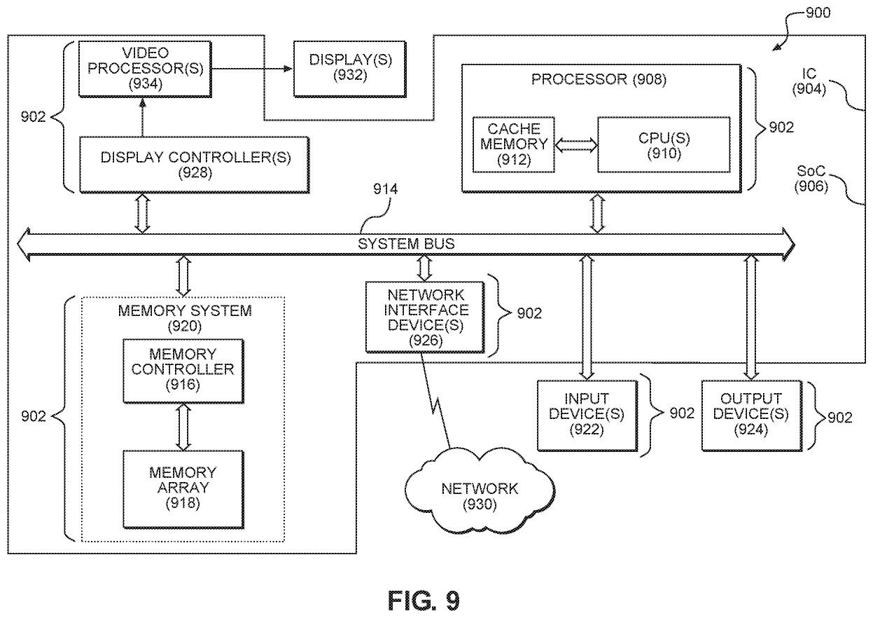

In this regard, FIG. 9 illustrates an example of a processor-based system 900 that can include a carbon nanotube gate FET 902, including but not limited to the carbon nanotube gate FET 302 in FIGS. 3A and 3B, and the 3D carbon nanotube dual-gate FET 602 in FIGS. 6A and 6B, and according to any aspects disclosed herein. In this example, the processor-based system 900 may be formed as an IC 904 in a system-on-a-chip (SoC) 906. The processor-based system 900 includes a processor 908 that includes one or more central processor units (CPUs) 910, which may also be referred to as CPU or processor cores. The processor 908 may have cache memory 912 coupled to the processor(s) 908 for rapid access to temporarily stored data. As an example, the cache memory 912 could include a carbon nanotube gate FET 902, including but not limited to the carbon nanotube gate FET 302 in FIGS. 3A and 3B, and the 3D carbon nanotube dual-gate FET 602 in FIG. 6A and 6B, and according to any aspects disclosed herein. The processor 908 is coupled to a system bus 914 and can intercouple master and slave devices included in the processor-based system 900. As is well known, the processor 908 communicates with these other devices by exchanging address, control, and data information over the system bus 914. For example, the processor 908 can communicate bus transaction requests to a memory controller 916 as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. Each of the memory system 920, the one or more input devices 922, the one or more output devices 924, the one or more network interface devices 926, and the one or more display controllers 928 can include a carbon nanotube gate FET 902, including but not limited to the carbon nanotube gate FET 302 in FIGS. 3A and 3B, and the 3D carbon nanotube dual-gate FET 602 in FIGS. 6A and 6B, and according to any aspects disclosed herein, and according to any aspects disclosed herein. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area. network (WLAN), a wide area network (WAN), a BLUETOOTH™ network, and the Internet. The network interface device(s) 926 can be configured to support any type of communications protocol desired.

The processor 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display(s) 932 can include any type of display, including, but not limited to, a cathode ray tube (CRT), a liquid crystal display (LCD), a plasma display, a light emitting diode (LED) display, etc. The display controller(s) 928, display(s) 932, and/or the video processor(s) 934 can include a carbon nanotube gate FETs 902, including but not limited to the carbon nanotube gate FET 302 in FIGS. 3A and 3B, and the 3D carbon nanotube dual-gate FET 602 in FIGS. 6A and 6B, and according to any aspects disclosed herein, and according to any aspects disclosed herein.

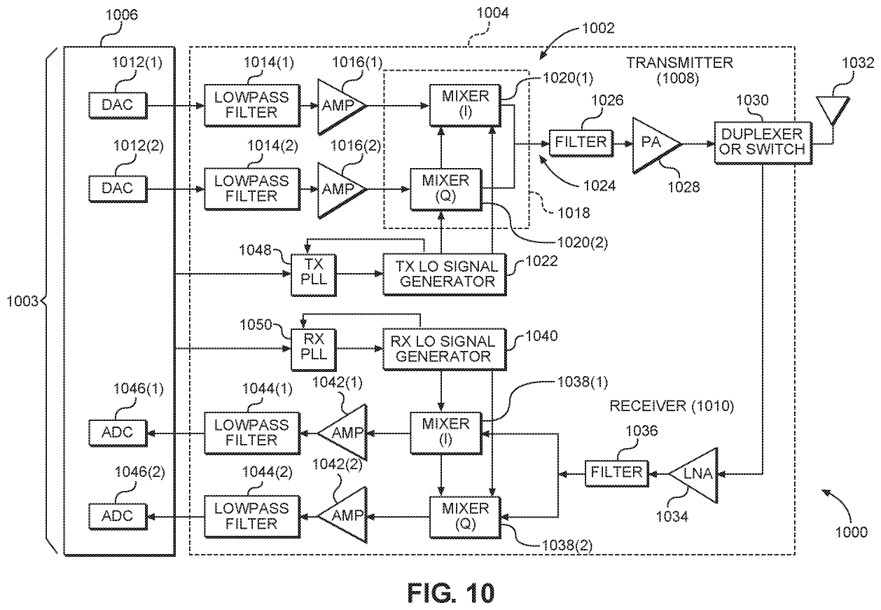

FIG. 10 illustrates an exemplary wireless communications device 1000 that includes radio frequency (RF) components formed from an IC 1002, wherein any of the components therein can include a carbon nanotube gate FET 1003, including but not limited to the carbon nanotube gate FET 302 in FIGS. 3A and 3B, and the 3D carbon nanotube dual-gate FET 602 in FIGS. 6A and 6B, and according to any aspects disclosed herein. The wireless communications device 1000 may include or be provided in any of the above referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture, in the super-heterodyne architecture, a signal is frequency-converted between RF and baseband in multiple stages, e.g., from RF to an intermediate frequency (IF) in one stage, and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals, e.g., I and Q output currents, for further processing.

Within the transmitter 1008, lowpass filters 1014(1), 1014(2) filter the I and Q analog output signals, respectively, to remove undesired signals caused by the prior digital-to-analog conversion. Amplifiers (AMPS) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency upconversion as well as noise in a receive frequency band, A power amplifier (PA) 1028 amplifies the upconverted signal 1024 from the filter 1026 to obtain the desired output power level and provides a transmitted RF signal. The transmitted RF signal is routed through a duplexer or switch 1030 and transmitted via an antenna 1032.

In the receive path, the antenna 1032 receives signals transmitted by base stations and provides a received RF signal, which is routed through the duplexer or switch 1030 and provided to a low noise amplifier (LNA) 1034. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Downconversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by amplifiers (AMPs) 1042(1), 1042(2) and further filtered by lowpass filters 1044(1), 1044(2) to obtain I and Q analog input signals, which are provided to the data processor 1006. In this example, the data processor 1006 includes ADCs 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency upconversion, while the RX LO signal generator 1040 generates the I and Q RX LO signals used for frequency downconversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration)

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

What is claimed is:

1. A three-dimensional (3D) field-effect transistor (FET), comprising:
a substrate comprising a top surface;
a dielectric layer disposed on the top surface of the substrate;
a carbon nanotube channel disposed above the dielectric layer, the carbon nanotube channel comprising at least one carbon nanotube channel structure each comprising:
a carbon nanotube having a first length and having a first longitudinal axis; and
a channel dielectric material surrounding at least a portion of the carbon nanotube; and
a carbon nanotube gate disposed above a portion of the carbon nanotube channel, the carbon nanotube gate comprising a carbon nanotube having a second longitudinal axis substantially orthogonal to the first longitudinal axis.

2. The 3D FET of claim 1, wherein the carbon nanotube gate is configured to control a channel mobility in the carbon nanotube channel based on a voltage applied to the carbon nanotube gate.

3. The 3D FET of claim 1, wherein the carbon nanotube channel is disposed on a top surface of the dielectric layer.

4. The 3D FET of claim 1, wherein:
the carbon nanotube gate has a gate length, and comprises a first gate side extending in the direction of the second longitudinal axis and a second gate side opposite the first gate side extending in the direction of the second longitudinal axis; and
the at least one carbon nanotube channel structure further comprises a first end portion extending in the direction of the first longitudinal axis beyond the first gate side of the carbon nanotube gate and a second end portion extending in the direction of the first longitudinal axis beyond the second gate side of the carbon nanotube gate.

5. The 3D FET of claim 4, wherein the carbon nanotube gate further comprises a first spacer disposed adjacent to the first gate side of the carbon nanotube gate and a second spacer disposed adjacent to the second gate side of the carbon nanotube gate.

6. The 3D FET of claim 4, further comprising:
a source disposed adjacent to the first end portion of the at least one carbon nanotube channel structure and the first gate side of the carbon nanotube gate; and
a drain disposed adjacent to the second end portion of the at least one carbon nanotube channel structure and the second gate side of the carbon nanotube gate.

7. The 3D FET of claim 1, further comprising:
a second dielectric layer disposed above the carbon nanotube gate;
a second carbon nanotube channel disposed above the second dielectric layer, the second carbon nanotube channel comprising at least one second carbon nanotube channel structure each comprising:
a second carbon nanotube having a second length and having a third longitudinal axis substantially parallel to the first longitudinal axis; and
a second channel dielectric material surrounding at least a portion of the second carbon nanotube; and
a second carbon nanotube gate disposed above a portion of the second carbon nanotube channel, the second carbon nanotube gate comprising a second carbon nanotube having a fourth longitudinal axis substantially orthogonal to the third longitudinal axis.

8. The 3D FET of claim 7, further comprising a third dielectric layer disposed above the second carbon nanotube gate.

9. The 3D FET of claim 1, wherein the carbon nanotube gate is a back carbon nanotube gate structure, and further comprising:
a front carbon nanotube gate disposed above a portion of the carbon nanotube channel, the front carbon nanotube gate comprising a front carbon nanotube gate structure comprising a front carbon nanotube having a third longitudinal axis substantially parallel to the second longitudinal axis.

10. The 3D FET of claim 1, wherein the channel dielectric material of the at least one carbon nanotube channel structure is half or less of the thickness of the carbon nanotube of the at least one carbon nanotube channel structure.

11. The 3D FET of claim 1, wherein the dielectric layer comprises a high-K dielectric material.

12. The 3D FET of claim 1, wherein the dielectric layer comprises a dielectric material comprised from the group consisting of Hafnium Oxide (HfOx), Hafnium Silicon Oxide (HfSiOx), and Hafnium Silicon Oxygen Nitride (HfON).

13. The 3D FET of claim 1 integrated into an semiconductor die.

14. The 3D FET of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

15. A method of fabricating a three-dimensional (3D) field-effect transistor (FET), comprising:
disposing a dielectric layer disposed on a top surface of a substrate;
transferring at least one carbon nanotube to a top surface of the dielectric layer to form a carbon nanotube channel structure, wherein the at least one carbon nanotube has a first length and has a first longitudinal axis;
disposing a channel dielectric layer over the at least one carbon nanotube;
transferring a second carbon nanotube above the channel dielectric layer and above a portion of the carbon nanotube channel structure to form a carbon nanotube gate having a second longitudinal axis substantially orthogonal to the first longitudinal axis and comprising a first gate side extending in the direction of the second longitudinal axis and a second gate side opposite the first gate side extending in the direction of the second longitudinal axis; and
forming a second dielectric layer above the carbon nanotube gate.

16. The method of claim 15, further comprising etching the at least one carbon nanotube to form the carbon nanotube channel structure of a first length in the direction of the first longitudinal axis.

17. The method of claim 15, further comprising:
depositing a film layer above the carbon nanotube gate;
etching the first gate side and the second gate side of the carbon nanotube gate; and
forming a first spacer adjacent to the first gate side of the carbon nanotube gate and a second spacer adjacent to the second gate side of the carbon nanotube gate.

18. The method of claim 15, further comprising etching the second carbon nanotube to form the carbon nanotube gate of a second length in the direction of the second longitudinal axis.

19. The method of claim 15, wherein a first end portion of the carbon nanotube channel structure extends in the direction of the first longitudinal axis beyond the first gate side of the carbon nanotube gate and a second end portion of the carbon nanotube channel structure extends in the direction of the first longitudinal axis beyond the second gate side of the carbon nanotube gate.

20. The method of claim 19, further comprising removing the second dielectric layer above the first end portion of the carbon nanotube channel structure to form a first opening above the first end portion of the carbon nanotube channel structure, and removing the second dielectric layer above the second end portion of the carbon nanotube channel structure to form a second opening above the first end portion of the carbon nanotube channel

21. The method of claim 20, further comprising:
disposing a source material in the first opening to form a source adjacent to the first end portion of the carbon nanotube channel structure and the first gate side of the carbon nanotube gate; and
disposing a drain material in the first opening to form a drain adjacent to the second end portion of the carbon nanotube channel structure and the second gate side of the carbon nanotube gate.

22. A three-dimensional (3D) field-effect transistor (FET), comprising:
a substrate comprising a top surface;
a dielectric layer disposed on the top surface of the substrate;
a back carbon nanotube gate disposed above the dielectric layer, the back carbon nanotube gate having a first longitudinal axis;
a semiconductor channel comprising a semiconductor channel structure disposed above the back carbon nanotube gate, the semiconductor channel having a second length and having a second longitudinal axis substantially orthogonal to the first longitudinal axis;
a first channel dielectric layer disposed between the back carbon nanotube gate and the semiconductor channel;
a second channel dielectric layer disposed on a top surface of the semiconductor channel; and
a front carbon nanotube gate disposed on a top surface of the second channel dielectric layer, the front carbon nanotube gate having a third longitudinal axis substantially parallel to the first longitudinal axis.

23. The 3D FET of claim 22, wherein the back carbon nanotube gate and the front carbon nanotube gate are configured to control a channel mobility in the semiconductor channel based on a voltage applied to the back carbon nanotube gate and the front carbon nanotube gate.

24. The 3D FET of claim 22, wherein the back carbon nanotube gate is disposed on a top surface of the dielectric layer.

25. The 3D FET of claim 22, wherein:
the back carbon nanotube gate has a back gate length, and comprises a first gate side extending in the direction of the first longitudinal axis and a second gate side opposite the first gate side extending in the direction of the first longitudinal axis;
the front carbon nanotube gate has a front gate length, and comprises a third gate side extending in the direction of the first longitudinal axis and a fourth gate side opposite the third gate side extending in the direction of the first longitudinal axis; and
the semiconductor channel structure further comprises a first end portion extending in the direction of the second longitudinal axis beyond the first gate side of the back carbon nanotube gate and the third gate side of the front carbon nanotube gate, and a second end portion extending in the direction of the second longitudinal axis beyond the second gate side of the back carbon nanotube gate and the fourth gate side of the front carbon nanotube gate.

26. The 3D FET of claim 25, further comprising:
a first spacer disposed adjacent to the first gate side of the back carbon nanotube gate and front carbon nanotube gate; and
a second spacer disposed adjacent to the second gate side of the back carbon nanotube gate and front carbon nanotube gate.

27. The 3D FET of claim 25, further comprising:
a source disposed adjacent to the first end portion of the semiconductor channel structure, and the first gate side of the back carbon nanotube gate and the front carbon nanotube gate; and
a drain disposed adjacent to the second end portion of the semiconductor channel structure, and the second gate side of the back carbon nanotube gate and the front carbon nanotube gate.

28. The 3D FET of claim 22, further comprising:
a third channel dielectric layer disposed on a top surface of the front carbon nanotube gate;
a second semiconductor channel comprising a second semiconductor channel structure disposed above the front carbon nanotube gate, the second semiconductor channel having a third length and having a fourth longitudinal axis substantially orthogonal to the first longitudinal axis;
a fourth channel dielectric layer disposed between the front carbon nanotube gate and the second semiconductor channel;
a fifth channel dielectric layer disposed on a top surface of the second semiconductor channel; and
a second front carbon nanotube gate disposed on a top surface of the fifth channel dielectric layer, the second front carbon nanotube gate having a fourth longitudinal axis substantially parallel to the first longitudinal axis.

29. The 3D FET of claim 22, wherein the first channel dielectric layer and the second channel dielectric layer each comprise a high-K dielectric material.

30. The 3D FET of claim 22, wherein the first channel dielectric layer and the second channel dielectric layer each comprise a dielectric material comprised from the group consisting of Hafnium Oxide (HfOx), Hafnium Silicon Oxide (HfSiOx), and Hafnium Silicon Oxygen Nitride (HfON).

31. The 3D FET of claim 1 integrated into a semiconductor die.

32. The 3D FET of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

33. A method of fabricating a three-dimensional (3D) field-effect transistor (FET), comprising:
disposing a dielectric layer disposed on a top surface of a substrate;
transferring a back carbon nanotube gate to a top surface of the dielectric layer, the back carbon nanotube gate having a first longitudinal axis;
disposing a first channel dielectric layer on the back carbon nanotube gate;
disposing a semiconductor channel structure to a top surface of the first channel dielectric layer to form a semiconductor channel, the semiconductor channel structure having a second longitudinal axis substantially orthogonal to the first longitudinal axis;
disposing a second channel dielectric layer on a top surface of the semiconductor channel structure; and
transferring a front carbon nanotube gate on a top surface of the second channel dielectric layer, the front carbon nanotube gate having a third longitudinal axis substantially parallel to the first longitudinal axis.

34. The method of claim 33, further comprising etching the back carbon nanotube gate to form the back carbon nanotube gate of a second length in the direction of the second longitudinal axis.

35. The method of claim 33, wherein:
the back carbon nanotube gate has a back gate length, and comprises a first gate side extending in the direction of the first longitudinal axis and a second gate side opposite the first gate side extending in the direction of the first longitudinal axis;
the front carbon nanotube gate has a front gate length, and comprises the first gate side extending in the direction of the first longitudinal axis and the second gate side opposite the first gate side extending in the direction of the first longitudinal axis;
the semiconductor channel structure further comprises a first end portion of the semiconductor channel structure extending in the direction of the first longitudinal axis beyond the first gate side of the back gate and a second end portion of the semiconductor channel structure extending in the direction of the first longitudinal axis beyond the second gate side; and
the first end portion of the semiconductor channel structure extends in the direction of the first longitudinal axis beyond a third gate side and the second end portion of the semiconductor channel structure extends in the direction of the first longitudinal axis beyond the second gate side.

36. The method of claim 35, further comprising:
etching the first gate side and the second gate side of the back carbon nanotube gate and the front carbon nanotube gate;
forming a first spacer adjacent to the first gate side;
etching the second gate side of the back carbon nanotube gate and the front carbon nanotube gate; and
forming a second spacer adjacent to the second gate side.

37. The method of claim 35, further comprising removing the dielectric layer above the first end portion of the semiconductor channel structure to form a first opening above the first end portion of the semiconductor channel structure, and removing the dielectric layer above the second end portion of the semiconductor channel structure to form a second opening above the first end portion of the semiconductor channel structure.

38. The method of claim 37, further comprising:
disposing a source material in the first opening to form a source adjacent to the first end portion of the semiconductor channel structure, and the first gate side of the back carbon nanotube gate and front carbon nanotube gate and
disposing a drain material in the second opening to form a drain adjacent to the second end portion of the semiconductor channel structure, and the second gate side of the back carbon nanotube gate and front carbon nanotube gate.
